(19) United States
(12) Patent Application Publication
(10) Pub. No.: US 2026/0089969 A1
(43) Pub. Date: Mar. 26, 2026

(54) MEMORY SYSTEM AND A METHOD FOR CONTROLLING MEMORY SYSTEM

(71) Applicant: Japan Science and Technology Agency, Kawaguchi-Shi (JP)

(72) Inventors: Zuocheng CAI, Tokyo (JP); Kasidit Toprasertpong, Tokyo (JP); Mitsuru Takenaka, Tokyo (JP); Shinichi Takagi, Tokyo (JP)

(21) Appl. No.: 19/406,338

(22) Filed: Dec. 2, 2025

Related U.S. Application Data
(63) Continuation of application No. PCT/JP2024/017271, filed on May 9, 2024.
(60) Provisional application No. 63/506,675, filed on Jun. 7, 2023.

(51) Int. Cl. H10B 51/30; G11C 11/22; H10D 30/01; H10D 30/69; H10D 62/80; H10D 62/83; H10D 64/68

(52) U.S. Cl. CPC H10B 51/30; G11C 11/223; G11C 11/2275; G11C 11/2297; H10D 30/701; H10D 62/83; H10D 62/875; H10D 64/689; H10D 30/0415

(57) ABSTRACT

A memory system including a memory cell array and a control circuit, the memory device includes a ferroelectric layer with a thickness of 3 nm or more and 7 nm or less, when the control circuit determines a number of times of executions of a program for the memory cell reaches a predetermined number of times, the control circuit applies a first positive pulse voltage having a pulse width of a (μsec) m times to the ferroelectric layer, and applies a second negative pulse voltage having a pulse width of b (μsec) n times to the ferroelectric layer so that Equation 1 and Equation 2 hold.

$$0.1 μsec ≦ a \times m < 250 μsec \qquad ( Equation 1 )$$

$$0.1 μsec ≦ b \times n < 250 μsec . \qquad ( Equation 2 )$$

### CROSS REFERENCE TO RELATED APPLICATIONS

This application is a Continuation of International Patent Application No. PCT/JP2024/017271, filed on May 9, 2024, which claims the benefit of priority to the Provisional Application No. 63/506,675, filed on Jun. 7, 2023, the entire contents of which are incorporated herein by reference.

### FIELD

One embodiment of the present invention relates to a memory device and a memory system. In particular, one embodiment of the present invention relates to a memory device including a ferroelectric layer and a memory system including the memory device.

### BACKGROUND

Recently, a memory device including a ferroelectric layer has been developed. As such a memory device, a memory cell in which hafnium oxide is used as a gate insulating layer of a transistor (MOS FET) has been developed. Such a transistor-type memory cell is called a FeFET (Ferroelectric FET). The FeFET is expected to be a non-volatile memory device that can be programmed and erased at high speed and can be driven with low power consumption (for example, Japanese laid-open patent publication No. 2019-160374 and Non Patent Literatures 1 to 3). The Non-Patent Literatures 1 to 3 are literatures published after the filing of U.S. Provisional Application No. 63/506,675, which claims priority under the Paris Convention in this application.

### Non-Patent Literature 1

Bong Ho Kim, Seong Kwang Kim, Song-hyeon Kuk, Yoon-Je Suh, Jaeyong Jeong, Joon Pyo Kim, Dae-Myeong Geum, and Sanghyeon Kim, “IL Scavenging and Recovery Strategies to Improve the Performance and Reliability of HZO-Based FeFETs,” IEEE International Electron Devices Meeting (IEDM), 18-3, 2023.

### Non-Patent Literature 2

C. H. Wu, J. Liu, X. T. Zheng, Y. M. Tseng, M. Kobayashi, V. P. H. Hu, and C. J. Su, “Robust Recovery Scheme for MFIS-FeFETs at Optimal Timing with Prolonged Endurance: Fast-Unipolar Pulsing (100 ns), Nearly Zero Memory Window Loss (0.02%), and Self-Tracking Circuit Design,” IEEE International Electron Devices Meeting (IEDM), 18-2, 2023.

### Non-Patent Literature 3

C. H. Wu, J. Liu, X. T. Zheng, H. F. Chuang, Y. M. Tseng, M. Kobayashi, C. J. Su, and V. P. H. Hu, “Innovative Recovery Strategy for MFIS-FeFETs at Optimal Timing With Robust Endurance: Fast-Unipolar Pulsing (100 ns), Nearly Zero Memory Window Loss (0.02%), and Self-Tracking Circuit Design,” IEEE Transactions on Electron Devices, 2024.

In the FeFET, an interface between a stacked thin film forming the FeFET (for example, an interface between a ferroelectric layer and a silicon oxide on a silicon substrate) is deteriorated due to an effect of a program voltage at the time of programming data to a memory cell and an erase voltage at the time of erasing data of the memory cell, resulting in a problem of degradation in a write endurance (endurance characteristics).

An object of the present invention is to provide a memory device with high endurance characteristics.

### SUMMARY

A memory device according to an embodiment of the present invention includes: a semiconductor layer; a gate electrode facing the semiconductor layer; an insulating layer provided between the semiconductor layer and the gate electrode; and a ferroelectric layer provided between the insulating layer and the gate electrode and containing hafnium oxide, a thickness of the ferroelectric layer is greater than 3 nm and less than 7 nm.

A memory device according to an embodiment of the present invention includes: an oxide semiconductor layer; a gate electrode facing the oxide semiconductor layer; and a ferroelectric layer provided between the oxide semiconductor layer and the gate electrode and containing hafnium oxide, a thickness of the ferroelectric layer is greater than 1 nm and less than 30 nm.

A memory system according to an embodiment of the present invention includes: a memory cell array with memory cells including a memory device arranged in a matrix; and a control circuit configured to control the memory cell array, wherein when the control circuit is configured to determine whether a number of times of executions of a program operation or an erase operation on the memory cell reaches a predetermined number of times, and if the number of times of executions reaches the predetermined number of times, the control circuit is configured to execute a voltage application process in which a first voltage of a first polarity and a second voltage of a second polarity opposite to the first polarity are applied to the ferroelectric layer, the first voltage is greater than a maximum voltage applied in the program operation, and the second voltage is greater than a maximum voltage applied in the erase operation.

A memory system according to an embodiment of the present invention includes: a plurality of memory cell arrays with a memory device arranged in a matrix; and a control circuit configured to control the plurality of memory cell arrays, wherein when the control circuit is configured to determine whether a bit error rate is a predetermined rate or more after the program operation or the erase operation is executed, and if the bit error rate is the predetermined rate or more, the control circuit is configured to execute a voltage application process in which a first voltage of a first polarity and a second voltage of a second polarity opposite to the first polarity are applied to the ferroelectric layer, the first voltage is greater than a maximum voltage applied in the program operation, and the second voltage is greater than a maximum voltage applied in the erase operation.

A memory system according to an embodiment of the present invention includes: a memory cell array with memory cells including a memory device arranged in a matrix; and a control circuit configured to control the memory cell array, wherein the memory device includes: a semiconductor layer; a gate electrode facing the semiconductor layer; an insulating layer provided between the semiconductor layer and the gate electrode; and a ferroelectric layer provided between the insulating layer and the gate electrode and containing hafnium oxide, the semiconductor layer contains silicon, the insulating layer is in contact with the semiconductor layer, the ferroelectric layer is in contact with the insulating layer, a thickness of the ferroelectric layer is greater than 3 nm and less than 7 nm, when the control circuit determines: whether a number of times of executions of a program operation or an erase operation on the memory cell reaches a predetermined number of times or whether a bit error rate is a predetermined rate or more, the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more, wherein the first voltage is greater than a maximum voltage applied in the program operation, and the second voltage is greater than a maximum voltage applied in the erase operation, in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and when a pulse width of the first pulse voltage is set to a (μsec) and a pulse width of the second pulse voltage is set to b (μsec),

$$0.1 μsec ≦ a \times m < 250 μsec \qquad ( Equation 1 )$$

$$0.1 μsec ≦ b \times n < 250 μsec . \qquad ( Equation 2 )$$

A method for controlling memory system according to an embodiment of the present invention includes: a memory cell array with memory cells including a memory device arranged in a matrix; and a control circuit configured to control the memory cell array, wherein the memory device includes: a semiconductor layer; a gate electrode facing the semiconductor layer; an insulating layer provided between the semiconductor layer and the gate electrode; and a ferroelectric layer provided between the insulating layer and the gate electrode and containing hafnium oxide, the semiconductor layer contains silicon, the insulating layer is in contact with the semiconductor layer, the ferroelectric layer is in contact with the insulating layer, a thickness of the ferroelectric layer is greater than 3 nm and less than 7 nm, when the control circuit determines: whether a number of times of executions of a program operation or an erase operation on the memory cell reaches a predetermined number of times; or whether a bit error rate is a predetermined rate or more, the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more, wherein the first voltage is greater than a maximum voltage applied in the program operation, and the second voltage is greater than a maximum voltage applied in the erase operation, in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and when a pulse width of the first pulse voltage is set to a (μsec) and a pulse width of the second pulse voltage is set to b (μsec),

$$0.1 μsec ≦ a \times m < 250 μsec \qquad ( Equation 1 )$$

$$0.1 μsec ≦ b \times n < 250 μsec . \qquad ( Equation 2 )$$

A memory system according to an embodiment of the present invention includes: a plurality of memory cell arrays with a memory device arranged in a matrix; and a control circuit configured to control the plurality of memory cell arrays, wherein the memory device includes: an oxide semiconductor layer; a gate electrode facing the oxide semiconductor layer; and a ferroelectric layer provided between the oxide semiconductor layer and the gate electrode and containing hafnium oxide, a thickness of the ferroelectric layer is greater than 1 nm and less than 30 nm, when the control circuit determines: whether a number of times of executions of a program operation or an erase operation on the memory cell reaches a predetermined number of times; or whether a bit error rate is a predetermined rate or more, the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more, wherein the first voltage is greater than a maximum voltage applied in the program operation, and the second voltage is greater than a maximum voltage applied in the erase operation, in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and when a pulse width of the first pulse voltage is set to a (μsec) and a pulse width of the second pulse voltage is set to b (μsec),

$$0.1 μsec ≦ a \times m < 250 μsec \qquad ( Equation 1 )$$

$$0.1 μsec ≦ b \times n < 250 μsec . \qquad ( Equation 2 )$$

A method for controlling memory system according to an embodiment of the present invention includes: a plurality of memory cell arrays with a memory device arranged in a matrix; and a control circuit configured to control the plurality of memory cell arrays, wherein the memory device includes: an oxide semiconductor layer; a gate electrode facing the oxide semiconductor layer; and a ferroelectric layer provided between the oxide semiconductor layer and the gate electrode and containing hafnium oxide, a thickness of the ferroelectric layer is greater than 1 nm and less than 30 nm, when the control circuit determines: whether a number of times of executions of a program operation or an erase operation on the memory cell reaches a predetermined number of times; or whether a bit error rate is a predetermined rate or more, the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more, wherein the first voltage is greater than a maximum voltage applied in the program operation, and the second voltage is greater than a maximum voltage applied in the erase operation, in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and when a pulse width of the first pulse voltage is set to a (μsec) and a pulse width of the second pulse voltage is set to b (μsec),

$$0.1 μsec ≦ a \times m < 250 μsec \qquad ( Equation 1 )$$

$$0.1 μsec ≦ b \times n < 250 μsec . \qquad ( Equation 2 )$$

### BRIEF DESCRIPTION OF THE DRAWINGS

FIG. 1 is a schematic cross-sectional view showing a FeFET according to an embodiment of the present invention.

FIG. 2 is a sequence diagram showing a method for manufacturing a FeFET according to an embodiment of the present invention.

FIG. 3 shows cross-sectional TEM images of a ferroelectric layer of a FeFET according to an embodiment of the present invention.

FIG. 4 is a diagram showing I_{d}-V_{g} characteristics of a FeFET according to an embodiment of the present invention.

FIG. 5 is a diagram showing a memory window (MW) of a FeFET according to an embodiment of the present invention.

FIG. 6 is diagram a showing endurance characteristics of a FeFET according to an embodiment of the present invention.

FIG. 7 is a diagram showing changes in I_{d}-V_{g} characteristics when low-voltage operation or high-voltage operation is performed on a FeFET according to an embodiment of the present invention.

FIG. 8 is a diagram showing changes in P—V characteristics when low-voltage operation or high-voltage operation is performed on a FeFET according to an embodiment of the present invention.

FIG. 9 is a diagram showing a mechanism of narrowing an MW of a FeFET when high-voltage operation is performed on a FeFET according to an embodiment of the present invention.

FIG. 10 is a diagram showing a mechanism of narrowing an MW of a FeFET when low-voltage operation is performed on a FeFET according to an embodiment of the present invention.

FIG. 11 is a diagram schematically showing a recovery operation after a cyclic operation for a FeFET according to an embodiment of the present invention.

FIG. 12 is a diagram showing a change in I_{d}-V_{g} characteristics due to a recovery operation after high-voltage operation and after low-voltage operation for a FeFET according to an embodiment of the present invention.

FIG. 13 is a diagram showing endurance characteristics before and after a recovery operation for a FeFET according to an embodiment of the present invention.

FIG. 14 is a diagram showing a polarity of a recovery pulse in a recovery operation after a cyclic operation for a FeFET according to an embodiment of the present invention.

FIG. 15 is a diagram showing a polarity of a recovery pulse in a recovery operation after a cyclic operation for a FeFET according to an embodiment of the present invention.

FIG. 16 is a diagram showing a polarity of a recovery pulse in a recovery operation after a cyclic operation for a FeFET according to an embodiment of the present invention.

FIG. 17 is a diagram showing a polarity dependence of a recovery pulse for an MW after a recovery operation of a FeFET according to an embodiment of the present invention.

FIG. 18 is a diagram showing a voltage dependence of a recovery pulse for an MW after a recovery operation of a FeFET according to an embodiment of the present invention.

FIG. 19 is a diagram showing a pulse width dependence of a recovery pulse for an MW after a recovery operation of a FeFET according to an embodiment of the present invention.

FIG. 20 is a schematic diagram of a memory chip according to an embodiment of the present invention.

FIG. 21 is a circuit diagram of a memory chip according to an embodiment of the present invention.

FIG. 22 is a schematic diagram of a memory system according to an embodiment of the present invention.

FIG. 23 is a flowchart showing a recovery operation of a memory system according to an embodiment of the present invention.

FIG. 24 is a flowchart showing a recovery operation of a memory system according to an embodiment of the present invention.

FIG. 25 shows a process flow for a FeFET having HZO thicknesses of 4.6 nm, 6 nm, 8 nm, and 11 nm, and TEM images of an HZO FeFET having HZO thicknesses of 4.6 nm and 11 nm.

FIG. 26A shows (a) a measurement setup for P—V. A drain, a source and a substrate are connected.

FIG. 26B shows (b) P—V characteristics of a FeFET having an HZO thickness of 11 nm. Measurement condition: 4 KHz.

FIG. 26C shows (c) P—V characteristics of a FeFET having an HZO thickness of 8 nm. Measurement condition: 4 KHz.

FIG. 26D shows (d) P—V characteristics of a FeFET having an HZO thickness of 6 nm. Measurement condition: 4 kHz.

FIG. 26E shows (e) P—V characteristics of a FeFET having an HZO thickness of 4.6 nm. Measurement condition: 4 KHz.

FIG. 27A shows (a) I_{d}-V_{g} curves of a FeFET having an HZO thickness of 11 nm. A drive voltage range is from “−0.5 to 2 V” to “−2 to 3.5 V.” Device size: W=10 μm, L=100 μm. Measurement condition: VD=50 mV.

FIG. 27B shows (b) I_{d}-V_{g} curves of a FeFET having an HZO thickness of 8 nm. A drive voltage range is from “−0.5 to 2 V” to “−2 to 3.5 V.” Device size: W=10 μm, L=100 μm. Measurement condition: VD=50 mV.

FIG. 27C shows (c) I_{d}-V_{g} curves of a FeFET having an HZO thickness of 6 nm. A drive voltage range is from “−0.25 to 1.75 V” to “−1.5 to 3.5 V.” Device size: W=10 μm, L=100 μm. Measurement condition: VD=50 mV.

FIG. 27D shows (d) I_{d}-V_{g} curves of a FeFET having an HZO thickness of 4.6 nm. A drive voltage range is from “−0.25 to 1.75 V” to “−1.5 to 3 V.” Device size: W=10 μm, L=100 μm. Measurement condition: VD=50 mV.

FIG. 28 shows an MW obtained from the DC I_{d}-V_{g} of FIG. 27 as a function of an HZO thickness.

FIG. 29A shows an MW of a FeFET having an HZO thickness of 11 nm as a function of program (positive) voltage and an erase (negative) voltage. Pulse width=1 μs.

FIG. 29B shows an MW of a FeFET having an HZO thickness of 8 nm as a function of program (positive) voltage and an erase (negative) voltage. Pulse width=1 μs.

FIG. 29C shows an MW of a FeFET having an HZO thickness of 6 nm as a function of program (positive) voltage and an erase (negative) voltage. Pulse width=1 μs.

FIG. 29D shows an MW of a FeFET having an HZO thickness of 4.6 nm as a function of program (positive) voltage and an erase (negative) voltage. Pulse width=1 μs.

FIG. 30 shows (a) fast I_{d}-V_{g} curves (pulse width=1 μs) and (b) a minimum S value (S.S.min) displayed as a function of a thickness of a FeFET having HZO thicknesses of 11 nm, 8 nm, 6 nm, and 4.6 nm.

FIG. 31 shows endurance characteristics of an MW of a FeFET having HZO thicknesses of 11 nm, 8 nm, 6 nm, and 4.6 nm, pulse width=1 μs, (a) when calculated from 2 V_{c} obtained in the P—V shown in FIG. 26 and electric fields across the HZO are the same (high-voltage cycle), (b) when the initial MW is the same (0.5 V) (low-voltage cycle).

FIGS. 32A to 32I show two MW narrowing mechanisms and proposed recovery signals.

FIG. 32A shows (a) the recovery signal to V_{g} for the FeFET having an HZO thickness of 4.6 nm is −2 V/3 V, 20 s, and the recovery signal to V_{g} for the other FeFET is −2 V/3.5 V, 22 s.

FIG. 32B shows (b) a diagram illustrating a degradation mechanism due to a high-voltage cycle.

FIG. 32C shows (c) fast I_{d}-V_{g} at the initial, after cycling, and after recovery by a high voltage (3.1 V/−2.1 V). The pulse width is 1 μs. A FeFET having an HZO thickness of 6 nm is used.

FIG. 32D shows (d) DC I_{d}-V_{g} at the initial and after recovery by a high voltage (3.1 V/−2.1 V). The pulse width is 1 μs. A FeFET having an HZO thickness of 6 nm is used.

FIG. 32E shows (e) P—V at the initial and after cycling. The pulse width is 1 μs. A FeFET having an HZO thickness of 6 nm is used.

FIG. 32F shows (f) a diagram illustrating a degradation mechanism due to a low-voltage cycle.

FIG. 32G shows (g) fast I_{d}-V_{g} at the initial, after cycling, and after recovery by a low voltage (2.7 V/−1.7 V). The pulse width is 1 μs. A FeFET having an HZO thickness of 6 nm is used.

FIG. 32H shows (h) DC I_{d}-V_{g} at the initial and after recovery by a low voltage (2.7 V/−1.7 V). The pulse width is 1 μs. A FeFET having an HZO thickness of 6 nm is used.

FIG. 32I shows (I) P—V at the initial, after cycling, and after recovery by a low voltage (2.7 V/−1.7 V). The pulse width is 1 μs. A FeFET having an HZO thickness of 6 nm is used.

FIG. 33A shows (a) endurance characteristics of an MW in a FeFET having an HZO thickness of 11 nm after a recovery pulse (three recovery cycles).

FIG. 33B shows (b) endurance characteristics of an MW in a FeFET having an HZO thickness of 8 nm after a recovery pulse (three recovery cycles).

FIG. 33C shows (c) endurance characteristics of an MW in a FeFET having an HZO thickness of 6 nm after a recovery pulse (three recovery cycles).

FIG. 33D shows (d) endurance characteristics of an MW in a FeFET having an HZO thickness of 4.6 nm after a recovery pulse (three recovery cycles).

FIG. 34A shows (a) DC I_{d}-V_{g} recovery characteristics of a FeFET having an HZO thickness of 11 nm. The inserted S value (S.S.) indicates the minimum S value (S.S.min) degradation from the initial state to the state after the third recovery. The unit is mV/dec.

FIG. 34B shows (b) DC I_{d}-V_{g} recovery characteristics of a FeFET having an HZO thickness of 8 nm. The inserted S value (S.S.) indicates the minimum S value (S.S.min) degradation from the initial state to the state after the third recovery. The unit is mV/dec.

FIG. 34C shows (c) DC I_{d}-V_{g} recovery characteristics of a FeFET having an HZO thickness of 6 nm. The inserted S value (S.S.) indicates the minimum S value (S.S.min) degradation from the initial state to the state after the third recovery. The unit is mV/dec.

FIG. 34D shows (a) DC I_{d}-V_{g} recovery characteristics of a FeFET having an HZO thickness of 4.6 nm. The inserted S value (S.S.) indicates the minimum S value (S.S.min) degradation from the initial state to the state after the third recovery. The unit is mV/dec.

FIG. 35 shows a summary of the two MW narrowing mechanisms and the effect of thickness scaling, which are the new findings of the present study.

FIG. 36 is a schematic cross-sectional view showing a FeFET according to an embodiment of the present invention.

FIG. 37 is a perspective view showing a configuration of a memory cell according to an embodiment of the present invention.

FIG. 38 is a diagram showing a boundary between a high voltage in high-voltage operation and a low voltage in low-voltage operation for a FeFET according to an embodiment of the present invention.

FIG. 39 is a diagram showing a boundary between a high voltage in high-voltage operation and a low voltage in low-voltage operation for a FeFET according to an embodiment of the present invention.

### DESCRIPTION OF EMBODIMENTS

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the width, the thickness, the shape, and the like of each part may be schematically represented in comparison with an actual embodiment to make the description clearer. However, the drawings are merely examples, and do not limit the interpretation of the present invention.

In describing an embodiment of the present invention, a direction from a substrate toward a gate electrode is expressed as “above”, and the opposite direction is expressed as “below”. However, the expression “above” or “below” merely describes the vertical relationship of each element. For example, the expression that the gate electrode is arranged on the substrate includes the case where another member is interposed between the substrate and the gate electrode. In addition, the expression “above” or “below” includes not only the case where the elements overlap in a plan view, but also the case where they don't. The expression “directly above” or “directly below” refers to the case where the elements overlap in a plan view.

In the present specification, the expressions “a includes A, B or C,” “a includes any of A, B and C,” and “a includes one selected from a group consisting of A, B, and C” do not exclude the case where a includes a plurality of combinations of A to C unless otherwise specified. Furthermore, these expressions do not exclude the case where a includes other elements.

### 1. First Embodiment

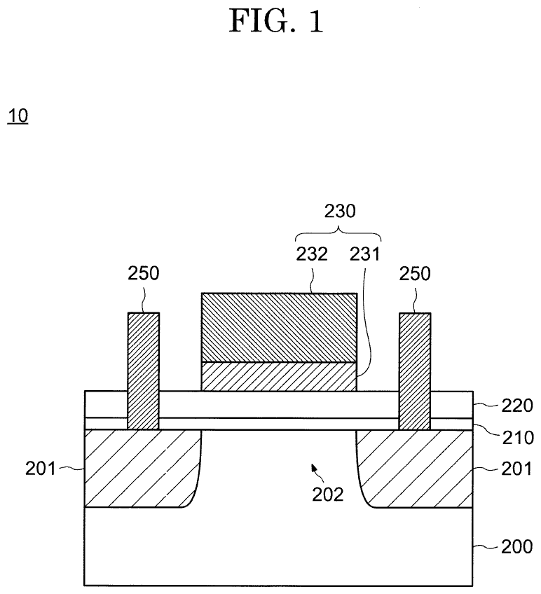

A configuration of a memory device 10 according to an embodiment of the present invention will be described with reference to FIG. 1 to FIG. 19. In the following embodiments, the memory device 10 in which a ferroelectric layer 220 is used as a layer having a memory function is exemplified. The memory device 10 is a MOSFET in which the ferroelectric layer 220 is used as a gate insulating layer, and is called a “FeFET”.

### 1-1. Configuration of Memory Device 10

FIG. 1 is a schematic cross-sectional view showing the FeFET according to an embodiment of the present invention. As shown in FIG. 1, the memory device 10 includes a semiconductor layer 200, an oxide insulating layer 210, the ferroelectric layer 220, a gate electrode 230, and an electrode 250. The semiconductor layer 200 may be a part (upper layer part) of a semiconductor substrate, and may be, for example, a semiconductor layer formed on an insulating layer substrate such as an SOI (Silicon on Insulator). The oxide insulating layer 210 is provided on the semiconductor layer 200. The ferroelectric layer 220 is provided on the oxide insulating layer 210. The oxide insulating layer 210 and the ferroelectric layer 220 may be referred to as the gate insulating layer. The gate electrode 230 is provided on the ferroelectric layer 220. The gate electrode 230 includes a first conductive layer 231 and a second conductive layer 232. Further, in the present embodiment, the gate electrode 230 has a two-layer structure, but the gate electrode 230 may have a one-layer structure or a structure having three layers or more.

In other words, the above configuration can be expressed as follows. The gate electrode 230 faces the semiconductor layer 200. The oxide insulating layer 210 is provided between the semiconductor layer 200 and the gate electrode 230. The ferroelectric layer 220 is provided between the oxide insulating layer 210 and the gate electrode 230. In addition, the oxide insulating layer 210 is also referred to as an interface layer, and the semiconductor layer 200 is also referred to as a channel layer.

The semiconductor layer 200 is provided with a low resistance region 201 and a channel region 202. The low resistance region 201 is a region that does not overlap the gate electrode 230 in a plan view. An impurity that reduces the resistance of the semiconductor layer 200 is introduced into the semiconductor layer 200 of the low resistance region 201. For example, in the case where the semiconductor layer 200 includes silicon and the memory device 10 is an N-type MOSFET, phosphorus (P) is used as the impurity, and when the memory device 10 is a P-type MOSFET, boron (B) is used as the impurity. The channel region 202 is a region sandwiched between two low resistance regions 201 which are spaced apart. One of the two low resistance regions 201 functions as a source region, and the other functions as a drain region. The semiconductor layer 200 of the channel region 202 has a property of being switched between an on-state and an off-state depending on a voltage supplied to the gate electrode 230.

The oxide insulating layer 210 is in contact with the semiconductor layer 200 of the channel region 202. The thickness of the oxide insulating layer 210 is less than 5 nm, 3 nm or less, 2 nm or less, 1 nm or less, or 0.7 nm or less. In either case, the thickness of the oxide insulating layer 210 is greater than 0 nm. For example, the oxide insulating layer 210 is a layer in which the semiconductor layer 200 is oxidized. In the case where the semiconductor layer 200 is a silicon substrate, the oxide insulating layer 210 contains silicon oxide. For example, the oxide insulating layer 210 can be obtained by applying a mixed solution of hydrochloric acid, hydrogen peroxide, and water to the semiconductor layer 200 or immersing the semiconductor layer 200 in the mixed solution. More specifically, the oxide insulating layer 210 is formed by an SC2 (Standard Clean 2) treatment included in an RCA cleaning. However, the oxide insulating layer 210 may be formed by thermal oxidation of the semiconductor layer 200.

The ferroelectric layer 220 is a dielectric layer in which electric dipoles are aligned even when an external electric field is not applied. The ferroelectric layer 220 is a dielectric layer in which the direction of the electric dipole is changed when an external electric field is applied. When such a ferroelectric layer 220 is used as the gate insulating layer, a threshold voltage in I_{d}-V_{g} characteristics (I_{d}: drain current, V_{g}: gate voltage) of the memory device 10 shifts depending on the direction of the electric dipole of the ferroelectric layer 220. Using such characteristics, the memory device 10 is used as a memory cell. In the present embodiment, a ferroelectric material containing hafnium oxide is used as the ferroelectric layer 220. For example, a mixed crystal (HZO; Hf_{0.5}Zr_{0.5}O₂) of hafnium oxide and zirconium oxide is used as the ferroelectric layer 220. The ferroelectric layer 220 is in contact with the oxide insulating layer 210. The thickness of the ferroelectric layer 220 is greater than 3 nm and less than 7 nm, or 4.6 nm or more and 6 nm or less.

Although the structure in which the ferroelectric layer 220 is in contact with the oxide insulating layer 210 is exemplified in the present embodiment, another layer may be provided between the ferroelectric layer 220 and the oxide insulating layer 210. The ferroelectric layer 220 may contain at least one of silicon, magnesium, aluminum, barium, zirconium, gadolinium, lanthanum, samarium, nitrogen, and yttrium in addition to hafnium and oxygen.

The gate electrode 230 is an electrode to which a voltage (gate voltage) for switching between the on-state and the off-state of the memory device 10 or a voltage (program voltage or erase voltage) for changing the direction of the electric dipole of the ferroelectric layer 220 is supplied. For example, titanium nitride, tungsten, tungsten nitride, ruthenium, and ruthenium oxide can be used as the first conductive layer 231. Aluminum and polycrystalline silicon can be used as the second conductive layer 232.

A contact is provided on the oxide insulating layer 210 and the ferroelectric layer 220. The contact reaches the low resistance region 201 of the semiconductor layer 200. A conductive layer is deposited inside the contact to form the electrode 250. Of the two electrodes 250, the electrode connected to the source region is a source electrode, and the electrode connected to the drain region is a drain electrode. A general metal material is used as the electrode 250. For example, tungsten that can be deposited by a CVD (Chemical Vapor Deposition) method is used as the electrode 250.

### 1-2. Method for Manufacturing Memory Device 10

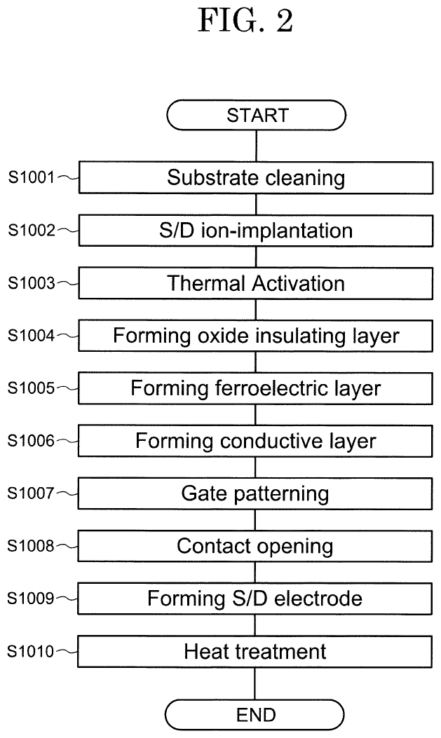

FIG. 2 is a sequence diagram showing a method for manufacturing the FeFET according to an embodiment of the present invention. As shown in FIG. 2, first, substrate cleaning is performed on the substrate including the semiconductor layer 200 (step S1001; Substrate Cleaning). For example, RCA cleaning is performed as the substrate cleaning. The RCA cleaning is cleaning including an SC1 treatment (Standard Clean 1) and the SC2 treatment as described above. The SC1 treatment is a treatment in which a mixed solution of an ammonium hydroxide solution, a hydrogen peroxide solution, and water is applied to the semiconductor layer 200 or the semiconductor layer 200 is immersed in the mixed solution.

Next, a mask in which a region that becomes the low resistance region 201 in a subsequent step is opened is formed by a photolithography process, and an impurity ion is implanted into the semiconductor layer 200 in the opened region (step S1002; S/D ion-implantation). Next, thermal activation is performed on the implanted impurity (step S1003; Thermal Activation). For example, the thermal activation in S1003 is performed by a heat treatment at 1000° C.

Next, the SC2 treatment is performed on a surface of the semiconductor layer 200. Through this SC2 treatment, the oxide insulating layer 210 is formed on the semiconductor layer 200 (step S1004; Forming oxide insulating layer). In the case where the oxide insulating layer 210 is formed by oxidation by chemical solution (chemical oxidation), the thickness of the formed oxide insulating layer 210 is very thin. Although details will be described later, in the present embodiment, the formed oxide insulating layer 210 has a thickness of about 0.7 nm.

Next, a ferroelectric layer 220 is formed on the oxide insulating layer 210 (step S1005; Forming ferroelectric layer). For example, the ferroelectric layer 220 is formed by an atomic layer deposition method (ALD). However, the ferroelectric layer 220 may be formed by other methods. Next, the first conductive layer 231 and the second conductive layer 232 (the gate electrode 230) are formed on the ferroelectric layer 220 (step S1006; Forming conductive layer). A mask is formed on the conductive layer formed in S1006, and the conductive layer is etched through the mask to form a pattern of the gate electrode 230 (step S1007; Gate patterning). Through S1007, the ferroelectric layer 220 is exposed in a region other than the region where the pattern of the gate electrode 230 is formed.

Next, a contact is opened in the ferroelectric layer 220 exposed by S1007 and the underlaying oxide insulating layer 210 (step S1008; Contact opening), and a conductive layer is deposited within the contact to form the electrode 250 (step S1009; Forming S/D electrode). After the electrode 250 is formed by S1009, a heat treatment is performed (step S1010; Heat treatment). For example, the heat treatment is performed at a condition of 400° C. and 30 seconds.

Further, in the present embodiment, although a manufacturing method in which the ion-implantation of S1002 is performed before forming the oxide insulating layer 210 is exemplified, the manufacturing method is not limited to this. For example, after the gate patterning of S1007, ions may be implanted into the semiconductor layer 200 using the gate pattern as a mask.

### 1-3. Cross-Sectional TEM Image of Ferroelectric Layer

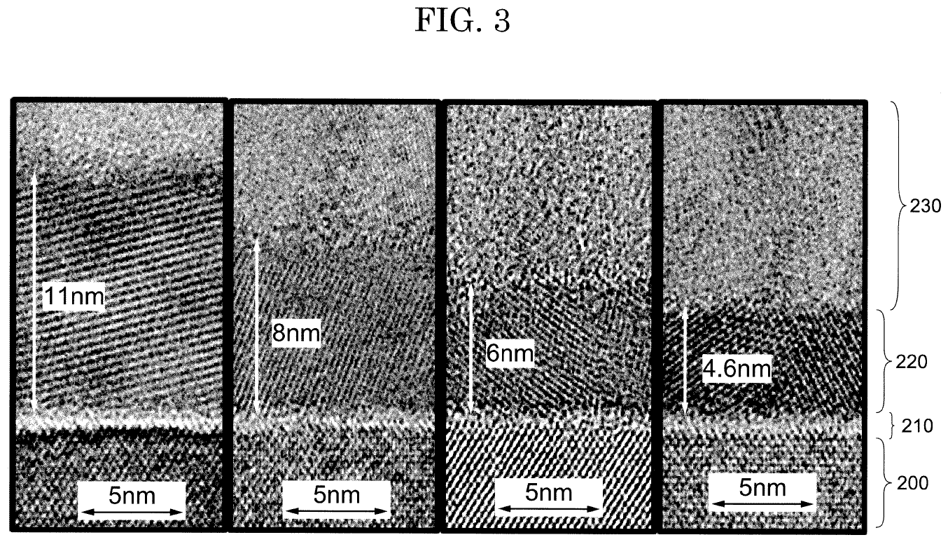

In the present embodiment, the memory device 10 shown in FIG. 1 was fabricated with different thicknesses of the ferroelectric layer 220, and various evaluations were performed. FIG. 3 shows cross-sectional TEM images of the ferroelectric layer of the FeFET according to an embodiment of the present invention. In FIG. 3, four cross-sectional TEM images are shown. FIG. 3 shows cross-sectional TEM images of the memory device 10 in which the thickness of the ferroelectric layer 220 is 11 nm, 8 nm, 6 nm, and 4.6 nm from the left. From the cross-sectional TEM images shown in FIG. 3, it is confirmed that the thickness of the ferroelectric layer 220 used in the present embodiment is substantially the numerical value described above, and that the ferroelectric layer 220 exhibits good crystallinity. In addition, from the cross-sectional TEM images shown in FIG. 3, it is confirmed that the thickness of the oxide insulating layer 210 is about 0.7 nm.

### 1-4. I_{d}-V_{g} Characteristics of Memory Device 10

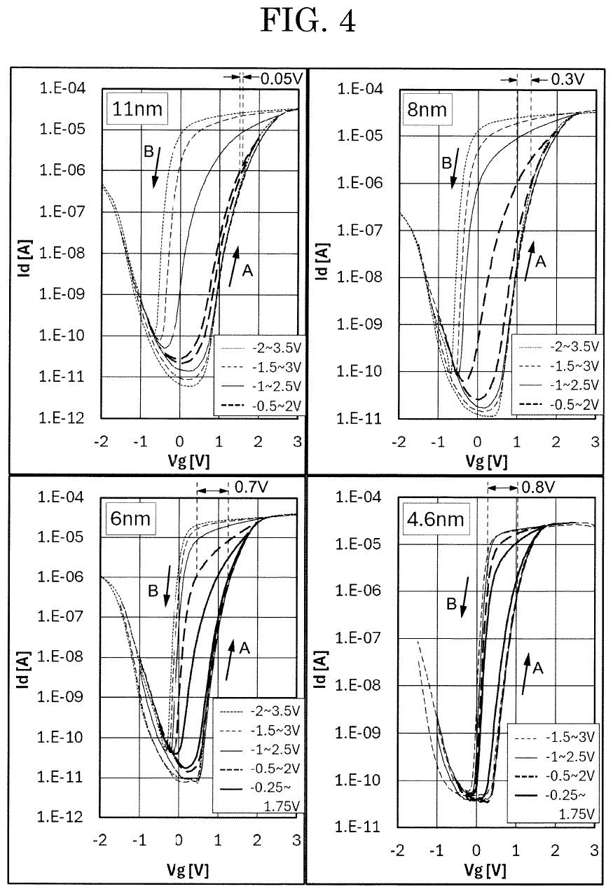

FIG. 4 is a diagram showing I_{d}-V_{g} characteristics of the FeFET according to an embodiment of the present invention. The four graphs shown in FIG. 4 are I_{d}-V_{g} characteristics measured for the four types of memory devices 10 with different thicknesses of the ferroelectric layer 220. V_{g} is a voltage applied to the gate electrode 230. I_{d} is a current flowing between the electrode 250 functioning as the source electrode and the electrode 250 functioning as the drain electrode. In addition, a distance (channel length) between the low resistance region 201 functioning as the source region and the low resistance region 201 functioning as the drain region is 10 μm, and a channel width perpendicular to the channel length is 100 μm. A drain voltage between the electrodes 250 at the time of measuring I_{d}-V_{g} characteristics is 0.05 V. In the I_{d}-V_{g} characteristics shown in FIG. 4, V_{g} is scanned while a voltage is continuously applied to the gate electrode 230, and polarization reversal occurs in the ferroelectric layer 220 when a high voltage is applied to V_{g}. Such I_{d}-V_{g} characteristics may be referred to as “DC I_{d}-V_{g}”.

In the graphs shown in FIG. 4, a plurality of I_{d}-V_{g} characteristics with different scan ranges of the gate voltage is displayed. In the graph of the memory device 10 in which the thickness of the ferroelectric layer 220 is 11 nm (upper left graph) and 8 nm (upper right graph), I_{d}-V_{g} characteristics when the scan range of the gate voltage is “−2 to 3.5 V (thin dot line)”, “−1.5 to 3 V (thin dashed line)”, “−1 to 2.5 V (thin solid line)”, and “−0.5 to 2 V (thick dashed line)” are shown. In the graph of the memory device 10 in which the thickness of the ferroelectric layer 220 is 6 nm (lower left graph), I_{d}-V_{g} characteristics when the scan range of the gate voltage is “−2 to 3.5 V (thin dot line)”, “−1.5 to 3 V (thin dashed line)”, “−1 to 2.5 V (thin solid line)”, “−0.5 to 2 V (thick dashed line)”, and “−0.25 to 1.75 V (thick solid line)” are shown. In the graph of the memory device 10 in which the thickness of the ferroelectric layer 220 is 4.6 nm (lower right graph), I_{d}-V_{g} characteristics when the scan range of the gate voltage is “−1.5 to 3 V (thin dashed line)”, “−1 to 2.5 V (thin solid line)”, “−0.5 to 2 V (thick dashed line)”, and “−0.25 to 1.75 V (thick solid line)” are shown.

The I_{d}-V_{g} characteristics shown in FIG. 4 are measured by first scanning in a direction (forward direction; A) from the minimum value toward the maximum value, folding back at the maximum value, and scanning in a direction (reverse direction; B) from the maximum value toward the minimum value in each scan range. In the case where the minimum voltage (the maximum negative voltage) is applied to Vg, the electric dipole of the ferroelectric layer 220 is polarized so that positive charges approach the gate electrode 230. When the voltage applied to V_{g} changes from a negative voltage to a positive voltage and Vg exceeds a predetermined positive voltage, the direction of the electric dipole is reversed. When the direction of the electric dipole is reversed, an electric field formed in the semiconductor layer 200 changes, and the threshold voltage of the memory device 10 shifts. Therefore, hysteresis occurs between I_{d}-V_{g} characteristics in the forward direction A and I_{d}-V_{g} characteristics in the reverse direction B. Due to this hysteresis, the threshold voltage of I_{d}-V_{g} characteristics (e.g., V_{g} when I_{d} is 10⁻⁶ A) differs between the forward and reverse directions. This difference in threshold voltage is called a memory window (MW).

When the MW for each thickness of the ferroelectric layer 220 is compared in the case where the scan range of the gate voltage is “−0.5 to 2 V (thick dashed line)”, a sufficient MW is obtained when the thickness of the ferroelectric layer 220 is 4.6 nm and 6 nm, as described below. In addition, the following MW values are the differences between the threshold voltage of I_{d}-V_{g} characteristics (V_{g} when I_{d} is 10⁻⁶ A) in the forward and reverse directions.

$$4.6 nm : MW = about 0.8 V$$

$$6 nm : MW = about 0.7 V$$

$$8 nm : MW = about 0.3 V$$

$$11 nm : MW = about 0.05 V$$

When the MW of the ferroelectric layer 220 at each thickness is evaluated in the case where the scan range of the gate voltage is “−0.25 to 1.75 V (thick solid line)”, the MW is about 0.5 V when the thickness of the ferroelectric layer 220 is 4.6 nm, while the MW is zero when the thickness of the ferroelectric layer 220 is 8 nm and 11 nm. Therefore, in the memory device 10 in which the thickness of the ferroelectric layer 220 is 11 nm (upper left graph) and 8 nm (upper right graph), I_{d}-V_{g} characteristics (thick solid line) are not shown.

If the thickness of the ferroelectric layer 220 is smaller than 7 nm, a sufficient MW can be obtained even in the low-voltage range of −0.5 to 2 V. On the other hand, in order to ensure polarization characteristics (ferroelectric characteristics) of the ferroelectric layer 220, the thickness of the ferroelectric layer 220 is preferably larger than 3 nm.

In order to reduce absolute values of the program voltage and the erase voltage of the memory device 10, it is required to reduce the thickness of the ferroelectric layer 220, but as described above, in view of the performance required for the memory device 10, the thickness of the ferroelectric layer 220 is preferably larger than 3 nm and smaller than 7 nm.

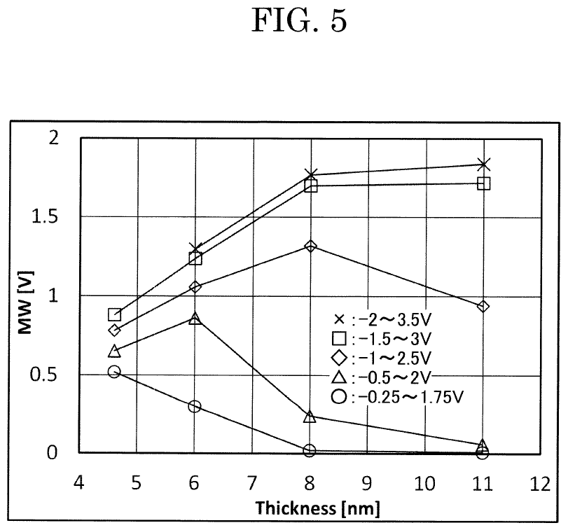

FIG. 5 is a diagram showing a memory window (MW) of the FeFET according to an embodiment of the present invention. The plot shown in FIG. 5 is the MW calculated from the graph of FIG. 4. In FIG. 4, the MW in the case where the scan range of the gate voltage is “−2 to 3.5 V (thin dot line)” is indicated by “x” in FIG. 5. In FIG. 4, the MW in the case where the scan range of the gate voltage is “−1.5 to 3 V (thin dashed line)” is indicated by “o” in FIG. 5. In FIG. 4, the MW in the case where the scan range of the gate voltage is “−1 to 2.5 V (thin solid line)” is indicated by “⋄” in FIG. 5. In FIG. 4, the MW in the case where the scan range of the gate voltage is “−0.5 to 2 V (thick dashed line)” is indicated by “A” in FIG. 5. In FIG. 4, the MW in the case where the scan range of the gate voltage is “−0.25 to 1.75 V (thick solid line)” is indicated by “o” in FIG. 5.

As shown in FIG. 5, in the case where the scan range of the gate voltage is relatively high (in particular, “x” and “□”), it is confirmed that the MW tends to become smaller as the thickness of the ferroelectric layer 220 decreases. Similarly, under the conditions where the thickness of the ferroelectric layer 220 is 11 nm and 8 nm, it is confirmed that the MW tends to become smaller as the scan range of the gate voltage is narrowed (along with “x”→“o”). On the other hand, in the case where the scan range of the gate voltage is relatively low (in particular, “Δ” and “o”), it is confirmed that the MW tends to become larger as the thickness of the ferroelectric layer 220 decreases. That is, as described above, the effect that the MW can be ensured even when the thickness of the ferroelectric layer 220 is thin and the scan range is low voltage is an effect that is recognized only in a singular range where the thickness of the ferroelectric layer 220 is larger than 3 nm and smaller than 7 nm, and the scan range of the gate voltage is “−0.5 to 2 V”. This effect is more significant particularly in a range where the thickness of the ferroelectric layer 220 is 4.6 nm or more and 6 nm or less, and the scan range of the gate voltage is “−0.25 to 1.75 V”.

### 1-5. Endurance Characteristics of Memory Device 10

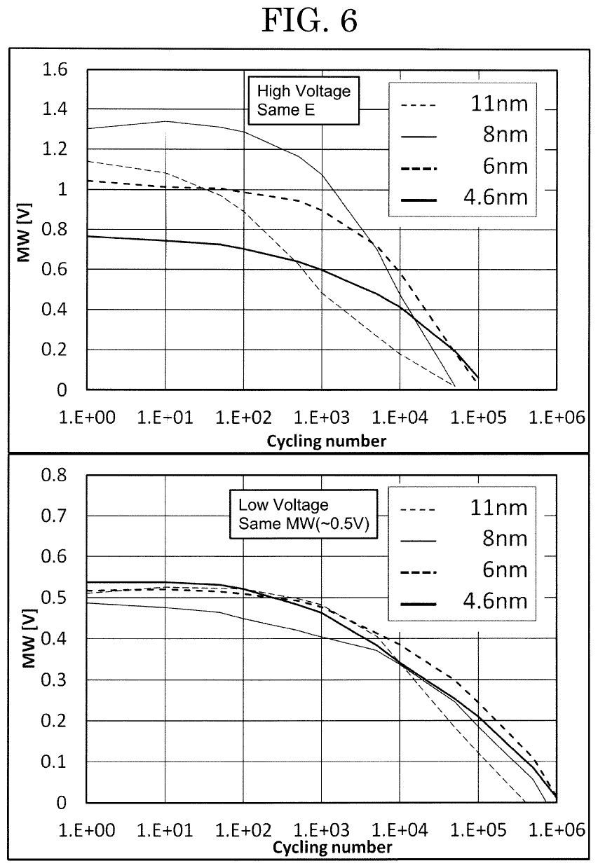

FIG. 6 is a diagram showing endurance characteristics of the FeFET according to an embodiment of the present invention. The two graphs in FIG. 6 both show the endurance characteristics of the memory device 10 due to cyclic operations. In these graphs, the horizontal axis represents the number of cycles (Cycling number) and the vertical axis represents the MW. In the cyclic operations, pulse voltages (a positive pulse voltage and a negative pulse voltage) corresponding to a program operation and an erase operation are repeatedly applied to the memory device 10. The positive pulse voltage and the negative pulse voltage are applied to the gate electrode 230 with 0 V applied to the electrodes 250. The pulse width of these pulse voltages is 1 μsec. The two graphs in FIG. 6 are different in conditions of the cyclic operations. The upper graph, labeled “High Voltage Same E,” is the endurance characteristics when the cyclic operations are performed at a relatively high voltage (voltage shown in Table 1 below). The lower graph, labeled “Low Voltage Same MW (to 0.5 V),” is the endurance characteristics when the cyclic operations are performed at a relatively low voltage (voltage shown in Table 2 below). In the following embodiment, the driving period from the start of the cyclic operations until MW becomes zero is referred to as the cycling number.

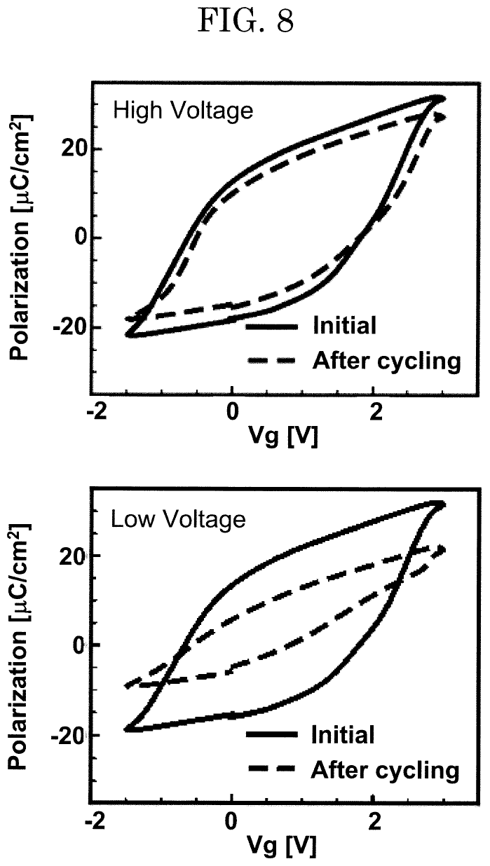

In the upper graph of FIG. 6, in order to suppress the effect of the electric field applied to the ferroelectric layer 220, the pulse voltage is adjusted so that the electric field strength in the ferroelectric layer 220 is constant. In the present embodiment, first, in the P—V measurement of the ferroelectric layer 220, a neutral voltage is obtained from a region where the polarization does not reverse, and the electric field strength of the ferroelectric layer 220 is obtained by dividing the potential difference from the neutral voltage by the thickness of the ferroelectric layer 220. In addition, for example, the neutral voltage is a voltage at the midpoint between a voltage at which the polarization becomes zero when the gate voltage V_{g} is scanned from the negative voltage to the positive voltage and a voltage at which the polarization becomes zero when the gate voltage V_{g} is scanned from the positive voltage to the negative voltage in the P—V characteristics shown in FIG. 8, which will be described later. By determining the electric field strength in this way, the effect of the electric field due to the difference in the thickness of the ferroelectric layer 220 can be reduced. The “positive pulse voltage/negative pulse voltage” for the thickness of the ferroelectric layer 220 is as shown in Table 1. In the present embodiment, the term “high-voltage operation” or “high-voltage cycle” means that the voltages shown in Table 1 are applied to each thickness of the ferroelectric layer 220.

TABLE 1

| | | |
|---|---|---|
| Thickness of | Positive | Negative |
| ferroelectric layer 220 | pulse voltage | pulse voltage |

| | | | | | |
|---|---|---|---|---|---|
| 4.6 | nm | 2.71 | V | −1.71 | V |
| 6 | nm | 3.1 | V | −2.1 | V |
| 8 | nm | 3.39 | V | −2.39 | V |
| 11 | nm | 3.5 | V | −2.5 | V |

In the lower graph of FIG. 6, the pulse voltage is adjusted based on the I_{d}-V_{g} characteristics shown in FIG. 4, for example, so that the MW of the memory device 10 is constant (MW=about 0.5). Specifically, the “positive pulse voltage/negative pulse voltage” with respect to the thickness of the ferroelectric layer 220 is as shown in Table 2. In the present embodiment, the term “low voltage operation” or “low-voltage cycle” means that the voltages shown in Table 2 are applied to each thickness of the ferroelectric layer 220.

TABLE 2

| | | |
|---|---|---|
| Thickness of | Positive | Negative |
| ferroelectric layer 220 | pulse voltage | pulse voltage |

| | | | | | |
|---|---|---|---|---|---|
| 4.6 | nm | 2.5 | V | −1.5 | V |
| 6 | nm | 2.7 | V | −1.7 | V |
| 8 | nm | 3.1 | V | −2.15 | V |
| 11 | nm | 3.15 | V | −2.3 | V |

As shown in the upper graph of FIG. 6, the cycling number (number of cyclic operations when the MW reaches 0 V) of the memory devices 10 in which the thicknesses of the ferroelectric layer 220 are 8 nm and 11 nm is about 5×10⁴ cycles, whereas the cycling number of the memory device 10 in which the thickness of the ferroelectric layer 220 is 4.6 nm and 6 nm is about 10⁵ cycles. Further, as shown in the lower graph of FIG. 6, the cycling number of the memory device 10 in which the thickness of the ferroelectric layer 220 is 4.6 nm and 6 nm reaches 10⁶ cycles.

As described above, by reducing the thickness of the ferroelectric layer 220 (to 4.6 nm and 6 nm), it was possible to obtain endurance characteristics of about 10⁵ cycles even under relatively high-voltage conditions. Further, by reducing the pulse voltage applied to the memory device 10, endurance characteristics of about 10⁶ cycles could be obtained.

### 1-6. Boundary Between High-Voltage Operation and Low-Voltage Operation

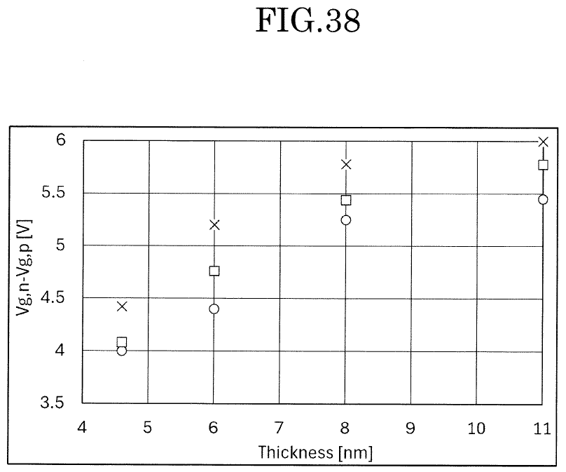

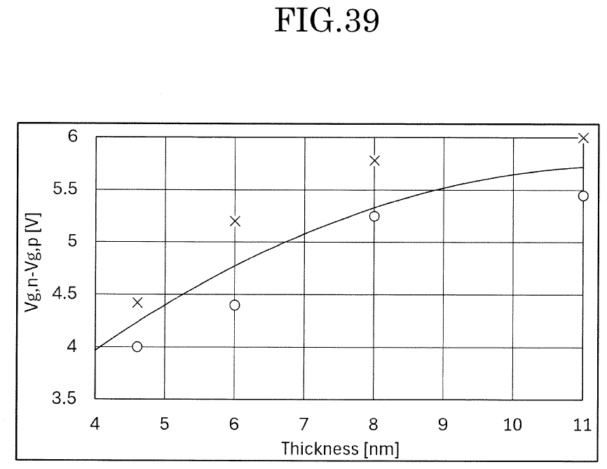

The boundary between the high voltage in the high-voltage operation and the low voltage in the low-voltage operation will be described. Although details will be described later, the boundary between the high voltage and the low voltage can be determined based on the P—V characteristics of the ferroelectric layer 220 or the thickness of the ferroelectric layer 220. FIG. 38 and FIG. 39 are diagrams showing the boundaries between the high voltage in the high-voltage operation and the low voltage in the low-voltage operation with respect to the FeFET according to an embodiment of the present invention, respectively.

First, a method for determining the boundary between the high voltage and the low voltage based on the P—V characteristics of the ferroelectric layer 220 will be described. In this case, first, a coercive voltage Ve is derived from the P—V characteristics of the ferroelectric layer 220. The coercive voltage Ve is the voltage required for the polarization (electric dipole) to begin switching from a state facing one direction to a state facing the opposite direction. That is, the coercive voltage Ve corresponds to, for example, a difference between the neutral voltage described above when the gate voltage V_{g} is scanned from the negative voltage to the positive voltage in the P—V characteristics shown in FIG. 8, which will be described later, and a voltage when the polarization value rises from the negative value and becomes zero.

In the case where the difference between the positive pulse voltage and the negative pulse voltage shown in Table 1 and Table 2 is expressed as a “range of write voltage,” it has been confirmed that there is a rule that the boundary between the high voltage and the low voltage is determined by a value obtained by multiplying the coercive voltage V_{c} by a coefficient of 3.4. That is, based on the boundary, it has been confirmed that the relationship between the range of the write voltage classified as the high voltage and the coercive voltage V_{c}, and the relationship between the range of the write voltage classified as the low voltage and the coercive voltage V_{c}, respectively, have the following regularities.
Range of write voltage classified as high voltage >3.4×V_{c}
Range of write voltage classified as low voltage <3.4×V_{c}

In FIG. 38, the vertical axis represents the write voltage (Vg, n-Vg, p[V]), and the horizontal axis represents the thickness (Thickness [nm]) of the ferroelectric layer 220. Based on Table 1 and Table 2, the range of the write voltage classified as the low voltage is indicated by “o” in FIG. 38, and the range of the write voltage classified as the high voltage is indicated by “x” in FIG. 38. The dielectric withstand voltage V_{c}×3.4 is indicated by “□” in FIG. 38. As shown in FIG. 38, in each thickness of the ferroelectric layer 220, the range of the write voltage greater than the dielectric withstand voltage V_{c}×3.4 “□” is classified as the high voltage, and the range of the write voltage smaller than the dielectric withstand voltage V_{c}×3.4 “□” is classified as the low voltage.

Next, a method for determining the boundary between the high voltage and the low voltage based on the thickness of the ferroelectric layer 220 will be described. In this case, as shown by the solid line in FIG. 39, the boundary between the high voltage and the low voltage can be derived from the following equation, where the thickness of the ferroelectric layer 220 is used as a function.

$$y = - 0.03 {x}^{2} + 0.7 x + 1.65$$

Further, in the equation described above, “x” represents the thickness (Thickness [nm]) of the ferroelectric layer 220, and “y” represents the write voltage (Vg, n-Vg, p[V]). In FIG. 39, the vertical axis and the horizontal axis are the same as the vertical axis and the horizontal axis in FIG. 38.

As shown in FIG. 39, in each thickness of the ferroelectric layer 220, a range of the write voltage greater than the equation described above (solid line in FIG. 39) is classified as the high voltage, and a range of the write voltage smaller than the equation described above is classified as the low voltage.

### 1-7. Fatigue Mechanism of Memory Device 10 Due to Cyclic Operations

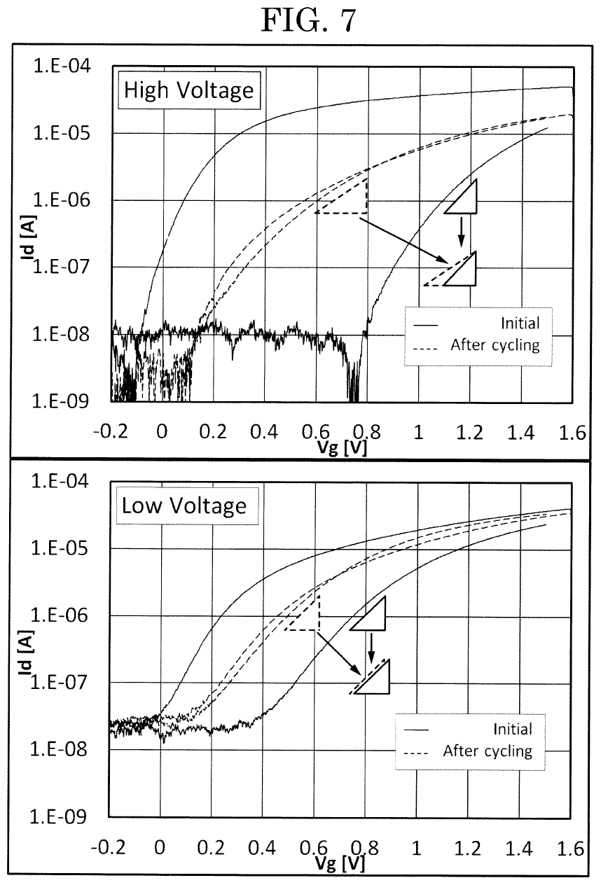

A fatigue mechanism of the memory device 10 due to cyclic operations will be described with reference to FIG. 7 to FIG. 10. Conventionally, it has been considered that the phenomenon in which the MW becomes smaller during cyclic operations of the memory cell using the ferroelectric layer (narrowing the MW) has been considered to be caused by, for example, interface degradation between the semiconductor layer 200 and the oxide insulating layer 210 and the interface between the oxide insulating layer 210 and the ferroelectric layer 220. Specifically, it has been considered that charge trap levels were generated at these interfaces by cyclic operations, and that the narrowing of the MW occurred as a result of charges being trapped in the trap levels. In addition, it was technically common knowledge that interfacial degradation could not be repaired by subsequent treatment.

In the process leading to the present invention, the inventors have found that the mechanism of narrowing the MW differs between the case where the high-voltage cyclic operations is performed on the memory cell and the case where the low-voltage cyclic operations is performed. The present inventors have clarified that the reason why the MW becomes smaller due to the low-voltage cyclic operations is due to fatigue of the ferroelectric layer, which is contrary to conventional common sense. Further, the inventors have established a method for recovering the fatigue of the ferroelectric layer, and have succeeded in increasing the MW, which had once become small due to cyclic operations, through recovery.

FIG. 7 is a diagram showing changes in I_{d}-V_{g} characteristics when low-voltage operation or high-voltage operation is performed on the FeFET according to an embodiment of the present invention. The I_{d}-V_{g} characteristics shown in FIG. 7 are I_{d}-V_{g} characteristics (solid line; Initial) before starting the cyclic operations and I_{d}-V_{g} characteristics (dashed line; After cycling) after the cyclic operations. The upper graph of FIG. 7 shows the I_{d}—V_{g} characteristics before and after the high-voltage cycle (High Voltage), and the lower graph shows the I_{d}-V_{g} characteristics before and after the low-voltage cycle (Low Voltage). The I_{d}-V_{g} characteristics shown in FIG. 7 are the I_{d}-V_{g} characteristics of the memory device 10 in which the thickness of the ferroelectric layer 220 is 6 nm. That is, the positive pulse voltage in the high-voltage cycle is 3.1 V and the negative pulse voltage is −2.1 V. On the other hand, the positive pulse voltage in the low-voltage cycle is 2.7 V and the negative pulse voltage is −1.7 V. The I_{d}-V_{g} characteristics shown in FIG. 7 were evaluated by applying a 1 μsec pulse voltage to the gate electrode 230 to change the direction of the electric dipole, and then performing a 0.1 sec V_{g} scan on the same gate electrode. By scanning V_{g} in this way, the effect on the polarization characteristics of the ferroelectric layer 220 during the evaluation of the I_{d}-V_{g} characteristics is small. Such I_{d}-V_{g} characteristics may be referred to as “fast I_{d}-V_{g}”.

The diagonal lines of the solid/dot right-angled triangles shown in FIG. 7 indicate the slopes near the threshold voltage in the I_{d}-V_{g} characteristics before/after the cyclic operations. As shown in the upper graph of FIG. 7, in the I_{d}-V_{g} characteristics before and after the high-voltage cycle, the S value changes significantly as the MW narrows. As can be seen from the diagonal lines of the solid line and dot right-angled triangles, the S value after the high-voltage cycle is greater than that before the high-voltage cycle. In other words, the rise of the current in the I_{d}-V_{g} characteristics becomes gradual due to the high-voltage cycle. On the other hand, as shown in the lower graph of FIG. 7, in the I_{d}-V_{g} characteristics before and after the low-voltage cycle, the S-value hardly changes despite the narrowing of the MW. From this phenomenon, it is considered that the mechanism of narrowing the MW due to the low-voltage cycle is different from the mechanism of narrowing the MW due to the high-voltage cycle.

Therefore, the P—V characteristics were measured before and after each of the high-voltage cycle and the low-voltage cycle, and the polarization characteristics of the ferroelectric layer 220 were examined, and are shown in FIG. 8. FIG. 8 is a diagram showing changes in the P—V characteristics when a low-voltage operation or high-voltage operation is performed on the FeFET according to an embodiment of the present invention. The P—V characteristics shown in FIG. 8 are P—V characteristics (solid line; Initial) before starting the cyclic operations and P—V characteristics (dashed line; After cycling) after the cyclic operations. The horizontal axis of the graph showing the P—V characteristics represents the gate voltage V_{g} [V], and the vertical axis represents the polarization [μC/cm²]. The upper graph (High Voltage) in FIG. 8 shows the P—V characteristics before and after the high-voltage cycle, and the lower graph (Low Voltage) shows the P—V characteristics before and after the low-voltage cycle. The P—V characteristics shown in FIG. 8 are P—V characteristics of the memory device 10 in which the thickness of the ferroelectric layer 220 is 6 nm. The pulse voltage in the high-voltage cycle and the low-voltage cycle is the same as the pulse voltage described in FIG. 7.

As shown in the upper graph in FIG. 8, there is no significant change in the P—V characteristics before and after the high-voltage cycle. On the other hand, as shown in the lower graph in FIG. 8, the P—V characteristics change significantly before and after the low-voltage cycle. That is, the polarization characteristics of the ferroelectric layer 220 change due to the low-voltage cycle. Such a phenomenon is referred to as “fatigue” of the ferroelectric. The ferroelectric fatigue is considered to be caused by a decrease in the amount of charge in the remanent polarization due to repeated polarization reversals.

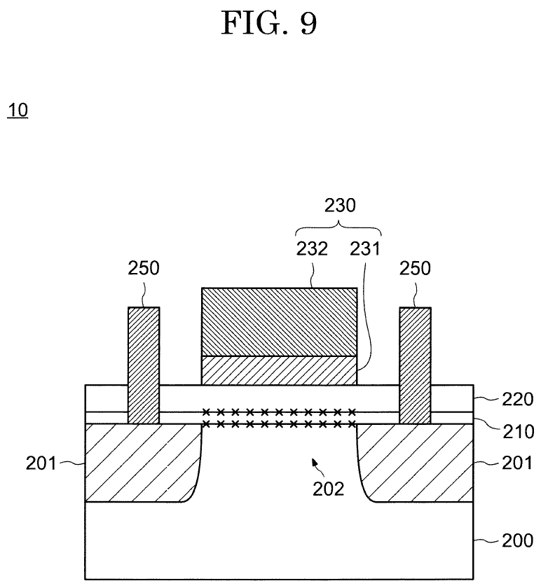

The pulse voltage applied to the memory device 10 by the high-voltage cycle is the same as the pulse voltage for the conventional memory cell. Therefore, the narrowing of the MW caused by the high-voltage cycle is considered to be caused by the charge trap level (“x” in FIG. 9) generated at the interface between the semiconductor layer 200 and the oxide insulating layer 210 and the interface between the oxide insulating layer 210 and the ferroelectric layer 220, as shown in FIG. 9. In addition, FIG. 9 is a diagram showing a mechanism of narrowing the MW of the FeFET when a high-voltage operation is performed on the FeFET according to an embodiment of the present invention. As shown in FIG. 7, the phenomenon in which the S value increases after the high-voltage cycle is considered to be due to electrons being trapped in the charge trap level generated near the interface between the semiconductor layer 200 and the oxide insulating layer 210 near the rising edge of the drain current I_{d}. On the other hand, as shown in FIG. 8, since the P—V characteristics hardly change before and after the high-voltage cycle, it is considered that the ferroelectric layer 220 is not fatigued by the high-voltage cycle.

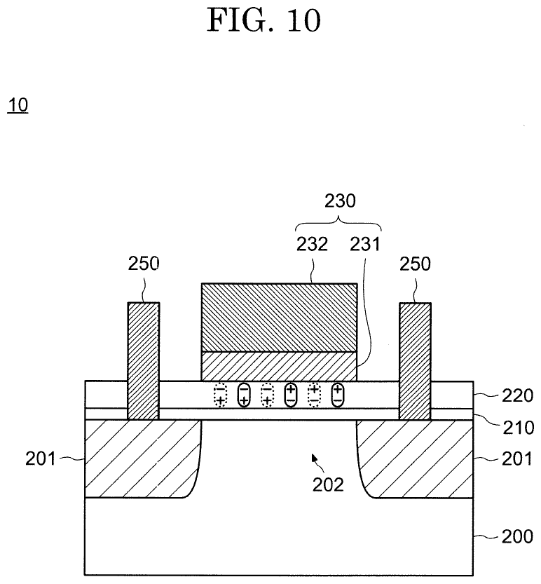

On the other hand, as shown in FIG. 7, the S value hardly changes before and after the low-voltage cycle. Therefore, it is considered that the narrowing of the MW caused by the low-voltage cycle is not caused by the interface degradation. As shown in FIG. 8, since the P—V characteristics changed significantly before and after the low-voltage cycle, it is considered that the ferroelectric layer 220 was fatigued due to the low-voltage cycle as shown in FIG. 10. Therefore, the narrowing of the MW caused by the low-voltage cycle is considered to be caused by the fatigue of the ferroelectric layer 220. FIG. 10 is a diagram showing a mechanism of narrowing the MW of the FeFET when a low-voltage operation is performed on the FeFET according to an embodiment of the present invention.

As described above, in the process leading to the present invention, the inventors have found that the mechanism of narrowing the MW by the low-voltage cycle differs from the mechanism of narrowing the MW by the high-voltage cycle. The inventors have clarified that the narrowing of the MW due to the low-voltage cycle is due to the fatigue of the ferroelectric layer.

### 1-8. Fatigue Recovery Operation of Ferroelectric Layer

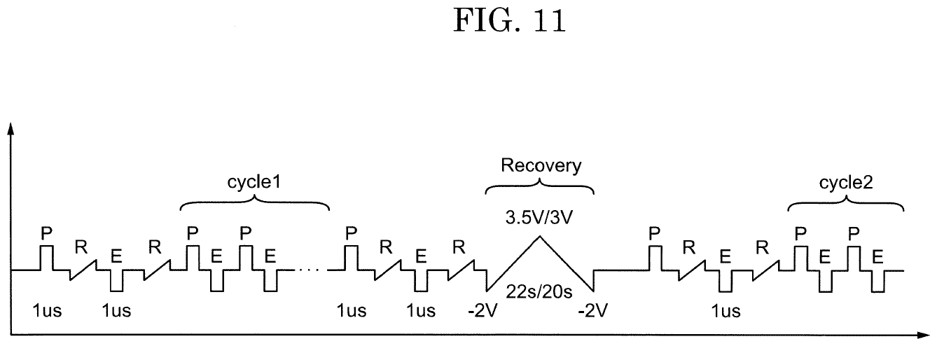

The fatigue recovery operation of the ferroelectric layer 220 will be described with reference to FIG. 11. FIG. 11 is a diagram schematically showing a recovery operation after a cyclic operations with respect to the FeFET according to an embodiment of the present invention. In FIG. 11, “P” indicates the positive pulse voltage corresponding to the program operation. “R” indicates an applied voltage corresponding to a read operation (measurement of the fast I_{d}-V_{g}). “E” indicates the negative pulse voltage corresponding to the erase operation. The pulse widths of the positive pulse voltage and the negative pulse voltage are both 1 μsec. “cycle1” indicates the first cyclic operations. “cycle2” indicates the second cyclic operations. “Recovery” indicates the recovery operation.

In the recovery operation, when the thickness of the ferroelectric layer 220 is 4.6 nm, the voltage is increased from −2 V to 3 V and decreased from 3 V to −2 V within 20 seconds. When the thickness of the ferroelectric layer 220 is 6 nm, 8 nm, or 11 nm, the voltage is increased from −2 V to 3.5 V and decreased from 3.5 V to −2 V within 22 seconds. In the example of FIG. 11, the recovery operation is performed in the order of seconds, but the recovery operation shown in FIG. 11 is a trial process, and although details will be described later, the recovery operation can be performed in a much shorter time in reality.

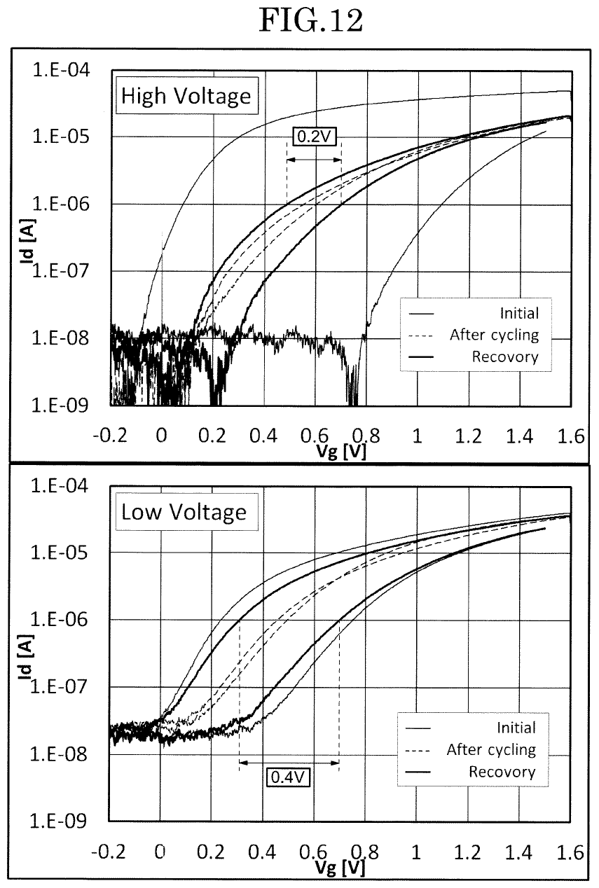

By the program operation and the erase operation, which are executed before the first cyclic operations, and the read operation after these operations, the I_{d}-V_{g} characteristics in the early stage (Initial) of FIG. 12, which will be described later, are obtained. In the first cyclic operations, the positive pulse voltage and the negative pulse voltage are alternately applied, and the read operation is performed every predetermined number of times to obtain endurance characteristics. The cyclic operations is terminated when the MW is determined to be zero in the endurance characteristics. I_{d}-V_{g} characteristics after the cycle (After cycling) of FIG. 12 described later are obtained by the program operation and the erase operation after the first cyclic operations, and the read operation after these operations. I_{d}-V_{g} characteristics after the recovery operation (Recovery) of FIG. 12 described later are obtained by the program operation and the erase operation after the recovery operation and before the second cyclic operations, and the read operation after these operations. Thereafter, the second cyclic operations is executed in the same manner as the first cyclic operations.

FIG. 12 is a diagram showing a change in I_{d}-V_{g} characteristics due to a recovery operation after a high-voltage operation or low-voltage operation with respect to the FeFET is performed according to an embodiment of the present invention. The I_{d}-V_{g} characteristics shown in FIG. 12 are I_{d}-V_{g} characteristics before starting the cyclic operations (thin solid line; Initial), I_{d}-V_{g} characteristics after cyclic operations (thin dashed line; After cycling), and I_{d}-V_{g} characteristics after the recovery operation (thick solid line; Recovery). The upper graph of FIG. 12 shows I_{d}-V_{g} characteristics before and after the high-voltage cycle (High Voltage), and the lower graph shows I_{d}-V_{g} characteristics before and after the low-voltage cycle (Low Voltage). The I_{d}-V_{g} characteristics shown in FIG. 12 are I_{d}-V_{g} characteristics of the memory device 10 in which the thickness of the ferroelectric layer 220 is 6 nm. That is, the positive pulse voltage in the high-voltage cycle is 3.1 V and the negative pulse voltage is −2.1 V. On the other hand, the positive pulse voltage in the low-voltage cycle is 2.7 V and the negative pulse voltage is −1.7 V.

The I_{d}-V_{g} characteristics shown in FIG. 12 are the fast I_{d}-V_{g} similar to those in FIG. 7. The I_{d}-V_{g} characteristics before (Initial) and after (After cycling) cyclic operations in the graph shown in FIG. 12 are the same as the I_{d}-V_{g} characteristics shown in FIG. 7. As shown in FIG. 12, in both the high-voltage cycle and the low-voltage cycle, the MW becomes larger after the recovery operation (Recovery).

The MW recovered by the recovery operation after the high-voltage cycle is about 0.2 V. The MW recovered by the recovery operation after the low-voltage cycle is about 0.4 V. However, the change in the MW before and after the low-voltage cycle is smaller than the change in the MW before and after the high-voltage cycle. That is, the effect of the recovery operation is greater in the low-voltage cycle. As described above, the narrowing of the MW due to the low-voltage cycle can be recovered by the recovery operation described above. That is, the fatigue of the ferroelectric layer 220 can be recovered by the recovery operation described above.

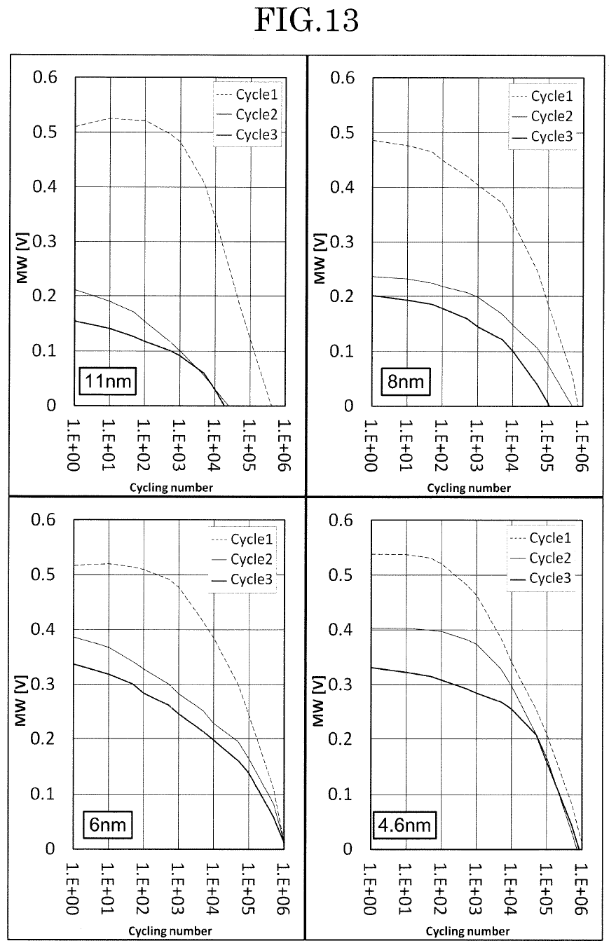

FIG. 13 is a diagram showing endurance characteristics after a recovery operation with respect to the FeFET according to an embodiment of the present invention. The four endurance characteristics shown in FIG. 13 are the endurance characteristics obtained based on the change in the MW due to the low-voltage cycle. In these graphs, the horizontal axis represents the cycling number (Cycling number) and the vertical axis represents the MW. The four graphs show the endurance characteristics with respect to the memory device 10 with different thicknesses of the ferroelectric layer 220. The upper left, upper right, lower left, and lower right graphs are endurance characteristics with respect to the memory device 10 in which the thickness of the ferroelectric layer 220 is 11 nm, 8 nm, 6 nm, and 4.6 nm, respectively.

The voltages shown in Table 2 are applied as the pulse voltage in the cyclic operations depending on the thickness conditions. In the graphs, endurance characteristics in the first cyclic operations (cycle1) (thin dashed line; Cycle1), endurance characteristics in the second cyclic operations (cycle2) (thin solid line; Cycle2), and endurance characteristics in the third cyclic operations (cycle3) (thick solid line; Cycle3) are displayed. The recovery operation shown in FIG. 11 is performed between the first and second cyclic operations and between the second and third cyclic operations.

Referring to the endurance characteristics with respect to the memory device 10 in which the thickness of the ferroelectric layer 220 is 11 nm (upper left graph), the initial MWs of cycle2 and cycle3 are less than or equal to half the initial MW of cycle1. In addition, the cycling number in cycle2 and cycle3 is about an order of magnitude smaller than the cycling number in cycle1. That is, in this condition, even if the recovery operation described above is performed, it is not possible to obtain a sufficient recovery effect on the endurance characteristics.

Referring to the endurance characteristics for the memory device 10 in which the thickness of the ferroelectric layer 220 is 8 nm (upper right graph), the initial MWs of cycle2 and cycle3 are about half of the initial MW of cycle1. In addition, the cycling number in cycle2 and cycle3 is smaller than the cycling number in cycle1. However, the cycling number in cycle2 and cycle3 of 8 nm condition are greater than those of above 11 nm condition. That is, under this condition, even if the recovery operation described above is performed, it is not possible to obtain a sufficient recovery effect on the endurance characteristics, but it is possible to obtain a recovery effect as compared with the 11 nm condition.

Referring to the endurance characteristics with respect to the memory device 10 in which the thickness of the ferroelectric layer 220 is 6 nm (lower left graph), the initial MWs of cycle2 and cycle3 are smaller than the initial MW of cycle1. However, the initial MWs of cycle2 and cycle3 are greater than the initial MWs of cycle2 and cycle3 of the above 11 nm conditions and 8 nm conditions. On the other hand, there is no significant difference in the cycling number from cycle1 to cycle3, and the cycling number reaches 10⁶ in all cycles. That is, under these conditions, a sufficient recovery effect on the endurance characteristics can be obtained by the recovery operation described above.

Referring to the endurance characteristics with respect to the memory device 10 in which the thickness of the ferroelectric layer 220 is 4.6 nm (lower right graph), the initial MWs of cycle2 and cycle3 are smaller than the initial MW of cycle1. However, compared with the 6 nm condition, the MW is less likely to decrease even if the cycling number increases. Although the cycling number in cycle2 and cycle3 is smaller than the cycling number in cycle1, the cycling number in cycle2 and cycle3 is still close to 10⁶ cycles. That is, under these conditions, a sufficient recovery effect on the endurance characteristics can be obtained by the recovery operation described above.

As described above, in the case where the low-voltage cycle is performed on the memory device 10 having the ferroelectric layer 220 with a thickness of 6 nm or less, it is possible to obtain a sufficient recovery effect on the endurance characteristics by the recovery operation.

### 1-9. Method of Applying Pulse Voltage in Recovery Operation

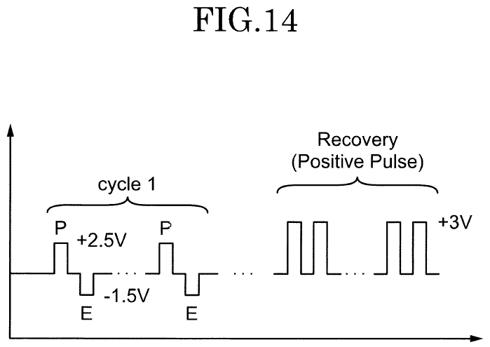

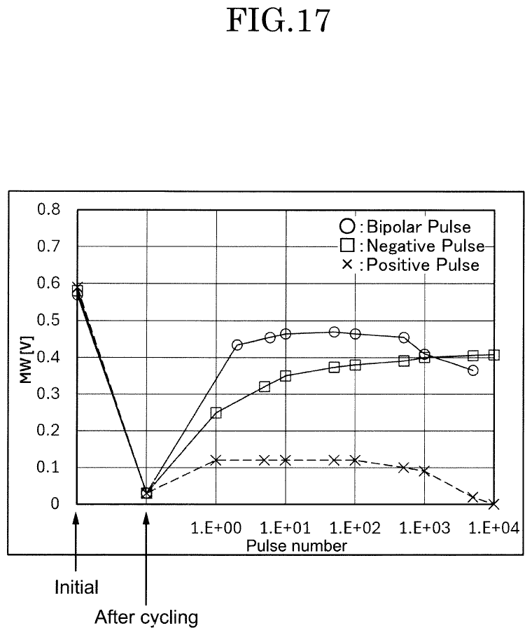

A method of applying the pulse voltage in the recovery operation and the results of evaluating the endurance characteristics after the recovery operation using each method will be described with reference to FIG. 14 to FIG. 19. FIG. 14 to FIG. 16 are diagrams showing polarities of recovery pulses in the recovery operation after the cyclic operations with respect to the FeFET according to an embodiment of the present invention. FIG. 17 to FIG. 19 are diagrams showing a polarity dependence, a voltage dependence, and a pulse width dependence of the recovery pulse for the MW after the recovery operation of the FeFET according to an embodiment of the present invention. In addition, FIG. 14 to FIG. 19 shows the method of applying the pulse voltage to the memory device 10 having the ferroelectric layer 220 with a thickness of 5.2 nm, and the evaluation results. The pulse voltage in the recovery operation is referred to as the “recovery pulse”.

FIG. 14 shows a method of applying the “positive pulse voltage (Positive Pulse)” as the recovery operation. In FIG. 14, the recovery operation (Recovery) is performed after cycle1. The cycle1 in FIG. 14 is the same as the cycle1 in FIG. 11. However, as described above, the thickness of the ferroelectric layer 220 of the memory device 10 described with reference to FIG. 14 to FIG. 19 is 5.2 nm, the positive pulse voltage in cycle1 is 2.5 V, and the negative pulse voltage is −1.5 V. Only the positive pulse voltage is applied to the ferroelectric layer 220 as the recovery pulse shown in FIG. 14. The positive pulse voltage in the recovery operation is 3 V and the pulse width is 1 μsec. The pulse waveform is substantially rectangular.

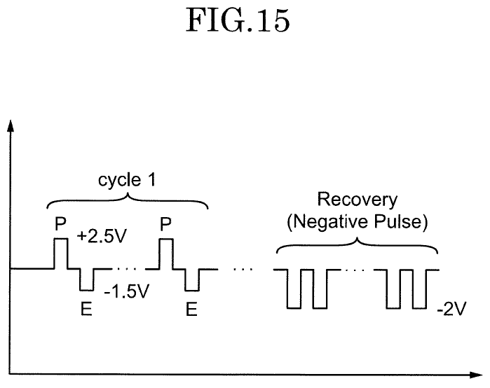

FIG. 15 shows a method of applying the “negative pulse voltage (Negative Pulse)” as the recovery operation. Only the negative pulse voltage is applied to the ferroelectric layer 220 as the recovery pulse shown in FIG. 15. Except for this point, the application method shown in FIG. 15 is the same as the application method shown in FIG. 14. The negative pulse voltage in the recovery operation is −2 V and the pulse width is 1 μsec. The pulse waveform is substantially rectangular.

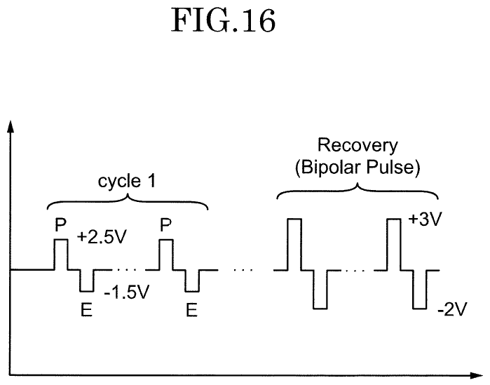

FIG. 16 shows a method of applying a “bipolar pulse voltage (Bipolar Pulse)” as the recovery operation. The positive pulse voltage and the negative pulse voltage are alternately applied to the ferroelectric layer 220 as the recovery pulse shown in FIG. 16. Except for this point, the application method shown in FIG. 16 is the same as the application method shown in FIG. 14. The positive pulse voltage in the recovery operation is 3 V, the negative pulse voltage is −2 V, and these pulse widths are 1 μsec. The pulse waveform is substantially rectangular.

FIG. 17 shows the results of evaluating the pulse voltage (recovery pulse) in the recovery operation shown in FIG. 14 to FIG. 16. FIG. 17 shows the MW after performing the recovery operation at a certain number of pulses after cyclic operations. In the graph of FIG. 17, the leftmost plot shows the MW before the start of cyclic operations (Initial), and the second plot from the left shows the MW after cyclic operations (After cycling). The third and subsequent plots from the left (the number of pulses (Pulse number) is 1 (1.E+00) and subsequent), respectively, show the MW measured after applying a predetermined number of pulse voltages. In FIG. 17, “o” indicates the evaluation result when the bipolar pulse voltage is applied. “□” indicates the evaluation result when the negative pulse voltage is applied. “x” indicates the evaluation result when the positive pulse voltage is applied. In each condition, when the positive pulse voltage or the negative pulse voltage is applied once, the number of pulses is counted by one. In addition, since one bipolar pulse voltage includes one positive pulse voltage and one negative pulse voltage, the minimum number of pulses of the bipolar pulse voltage is 2.

As shown in FIG. 17, the largest MW is obtained when the bipolar pulse voltage is applied in the recovery operation. On the other hand, the smallest MW is obtained when the positive pulse voltage is applied. In the recovery operation, under the conditions of applying the bipolar pulse voltage and the negative pulse voltage, the narrowed MW can be efficiently recovered. In particular, under the condition of applying the bipolar pulse voltage, a significant MW recovery effect was obtained with only 2 pulses (2.E+0). On the other hand, under the condition of applying the positive pulse voltage in the recovery operation, the maximum MW recovery effect was only about 0.1 V when a pulse voltage was applied from 0 to 10⁴ times. That is, in the recovery operation, a good MW can be obtained by applying the bipolar pulse voltage.

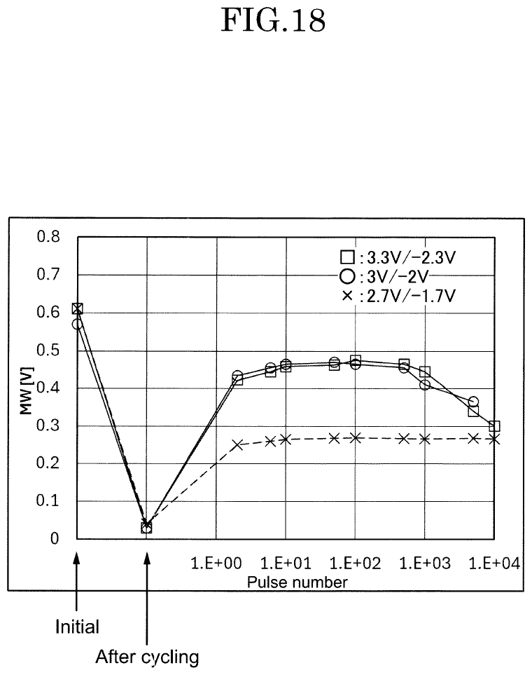

FIG. 18 shows the results of evaluating the voltage dependence of the positive pulse voltage and the negative pulse voltage in the method of applying the bipolar pulse voltage in the recovery operation. In FIG. 18, [positive pulse voltage/negative pulse voltage] in the recovery operation are [2.7 V/−1.7 V], [3 V/−2 V], and [3.3 V/−2.3 V]. These pulse widths are 1 μsec. In FIG. 18, “□” indicates an evaluation result when [3.3 V/−2.3 V] is applied as the pulse voltage in the recovery operation. “o” indicates an evaluation result when [3 V/−2 V] is applied as the pulse voltage. “x” indicates an evaluation result when [2.7 V/−1.7 V] is applied as the pulse voltage.

As shown in FIG. 18, a result was obtained that the MW after the recovery operation under the conditions of [3 V/−2 V] and [3.3 V/−2.3 V] is larger than the MW after the recovery operation under the conditions of [2.7 V/−1.7 V]. That is, in the recovery operation, by applying a voltage of 3 V or more as the positive pulse voltage and applying a voltage of −2 V or less as the negative pulse voltage, a good MW can be obtained.

The positive pulse voltage may be referred to as a “first pulse voltage”, and the negative pulse voltage may be referred to as a “second pulse voltage”. In addition, the voltage applied by the first pulse voltage may be referred to as a “first voltage”, and the voltage applied by the second pulse voltage may be referred to as a “second voltage”. In this case, the pulse voltage conditions for obtaining a good MW after the recovery operation as described above can be expressed as follows. The first voltage is positive and the absolute value of the first voltage is 3.0 V or more. The second voltage is negative and the absolute value of the second voltage is 2.0 V or more.

In addition, considering the breakdown voltage of the oxide insulating layer 210 and the ferroelectric layer 220, the absolute values of the first voltage and the second voltage are preferably 8.0 V or less. In other words, the positive pulse voltage is preferably 3.0 V or more and 8.0 V or less. The negative pulse voltage is preferably −8.0 V or more and −2.0 V or less.

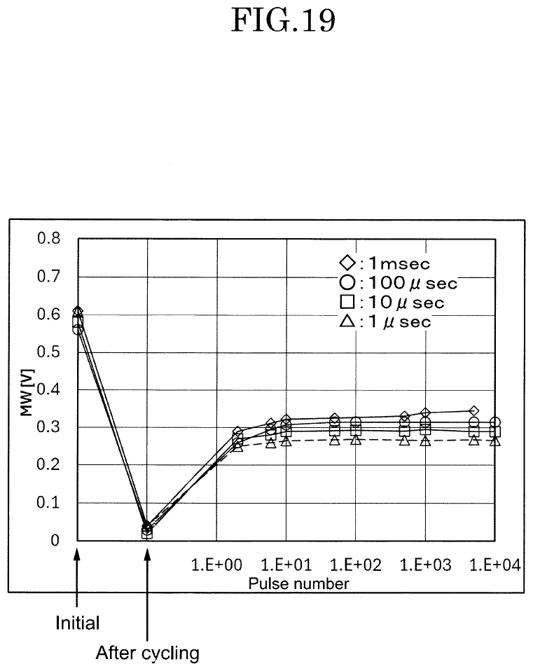

FIG. 19 shows the result of evaluating the pulse width dependence in the method of applying the bipolar pulse voltage in the recovery operation. In FIG. 19, [positive pulse voltage/negative pulse voltage] in the recovery operation is [2.7 V/−1.7 V], and the pulse widths of the pulse voltages are 1 μsec, 10 μsec, 100 μsec, and 1 msec. In FIG. 19, “⋄” indicates an evaluation result when the pulse width is 1 msec. “o” indicates an evaluation result when the pulse width is 100 μsec. “□” indicates an evaluation result when the pulse width is 10 μsec. “Δ” indicates an evaluation result when the pulse width is 1 μsec.

As shown in FIG. 19, the larger the pulse width, the larger the MW after the recovery operation tends to be, but the change in the MW relative to the pulse width is not large within the pulse width range of 1 μsec to 1 msec, and a good MW can be obtained under any condition. In addition, although the minimum value of the pulse width in FIG. 19 is 1 μsec, the pulse width for which the effect of the recovery operation is obtained in the present embodiment is 0.1 μsec or more. Furthermore, the pulse width may be 0.2 μsec or more, 0.3 μsec or more, or 0.5 μsec or more.

From the results shown in FIG. 17, in the recovery operation, the MW recovery effect can be obtained by applying the negative voltage to the ferroelectric layer 220. In addition, by alternately and repeatedly applying the negative pulse voltage and the positive pulse voltage to the ferroelectric layer 220, a higher MW recovery effect can be recovered.

As can be seen from the results of FIG. 19, the effect of recovering the fatigue of the ferroelectric layer 220 by the recovery operation is affected by the total time of the pulse voltage applied to the ferroelectric layer 220. Therefore, for example, if the number of times the positive pulse voltage is applied is m (m is an integer of 1 or more), the number of times the negative pulse voltage is applied is n (n is an integer of 1 or more), the pulse width of the positive pulse voltage is a usec, the pulse width of the negative pulse voltage is b usec, and the conditions suitable for the recovery operation can be expressed as Equation 1 and Equation 2.

$$0.1 μsec ≦ a \times m < 250 μsec \qquad ( Equation 1 )$$

$$0.1 μsec ≦ b \times n < 250 μsec \qquad ( Equation 2 )$$

In the case where the value of a×m is less than the lower limit of Equation 1 and the value of b×n is less than the lower limit of Equation 2, the recovery of the fatigue of the ferroelectric layer 220 is insufficient, and the MW is not sufficiently recovered. In the case where the value of a×m is the upper limit or more of Equation 1 and the value of b×n is the upper limit or more of Equation 2, the time required for the recovery operation in a memory system 20 to be described later becomes long, which causes discomfort to the user.

As described above, since the thickness of the ferroelectric layer 220 is larger than 3 nm and smaller than 7 nm, the low-voltage cyclic operations is possible, and the memory device 10 with high endurance characteristics can be realized. Furthermore, even when the MW is narrowed due to the low-voltage cyclic operations, the bipolar pulse voltage is applied as the pulse voltage in the recovery operation, the positive pulse voltage in the bipolar pulse voltage is 3 V or more, the negative pulse voltage is −2 V or less, and the pulse width of these pulse voltages is 0.1 μsec or more, so that the narrowed MW can be recovered (enlarged), and the memory device 10 with high endurance characteristics can be realized even after the recovery operation.

### 2. Second Embodiment

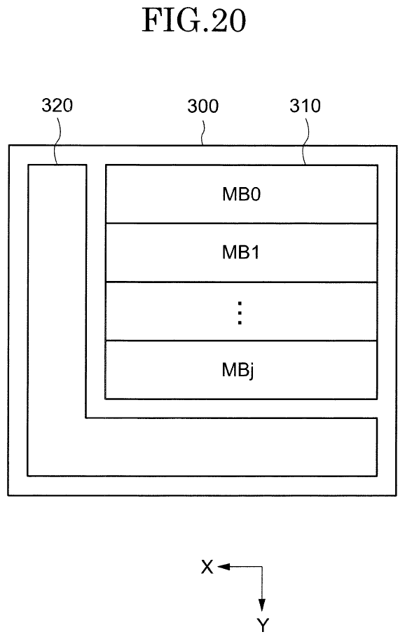

A memory chip 300 using the memory device 10 described in the first embodiment will be described with reference to FIG. 20 to FIG. 24.

### 2-1. Configuration of Memory Chip 300

FIG. 20 is a schematic diagram of a memory cell array according to an embodiment of the present invention. As shown in FIG. 20, the memory chip 300 includes a memory cell array 310 and a peripheral circuit 320. The peripheral circuit 320 is provided around the memory cell array 310. In the present embodiment, the peripheral circuit 320 is provided in a direction X and a direction Y of the memory cell array 310.

The memory cell array 310 includes a plurality of memory blocks MB0 to MBj arranged in the direction Y (j is a natural number). Each of the memory blocks MB0 to MBj includes a plurality of pages. In each page, a memory cell including the memory device 10 described above is arranged in a matrix. The page is a unit for executing the data read operation and the program operation. On the other hand, the memory block MBi (i is an integer of 0 or more and j or less) is a unit for executing a data erase operation.

The peripheral circuit 320 generates a voltage in response to an instruction received from the outside, and applies the generated voltage to the memory cell array 310 to perform the program operation, the read operation, or the erase operation on a page or a memory block specified by the instruction.

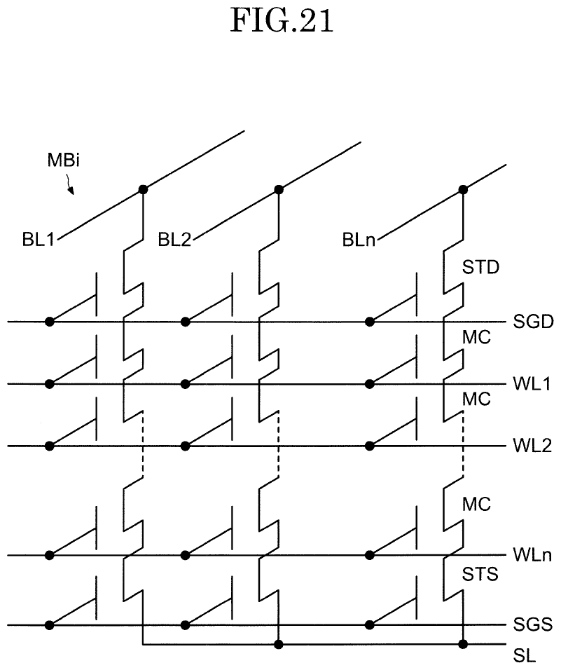

FIG. 21 is a circuit diagram of a memory cell array according to an embodiment of the present invention. A circuit diagram shown in FIG. 21 is an equivalent circuit diagram showing a configuration of one memory block MBi. The memory block MBi includes a memory cell MC, select transistors STD and STS, a bit line BL (BL1 to BLm), a source line SL, a word line WL (WL1 to WLn), and select gate lines SGD and SGS. The memory device 10 described in the first embodiment is used as the memory cell MC. m and n are natural numbers of 2 or more.

The memory cell MC and the select transistors STD and STS are directly connected between the bit line BL and the source line SL. As described above, a plurality of memory cells MC directly connected between the bit line BL and the source line SL may be referred to as a memory string.

The peripheral circuit 320 controls the voltage supplied to the bit line BL, the source line SL, the word line WL, and the select gate lines SGD and SGS to perform the program operation, the read operation, or the erase operation on the page or the memory block specified by the instruction.

### 2-2. Configuration of Memory System 20

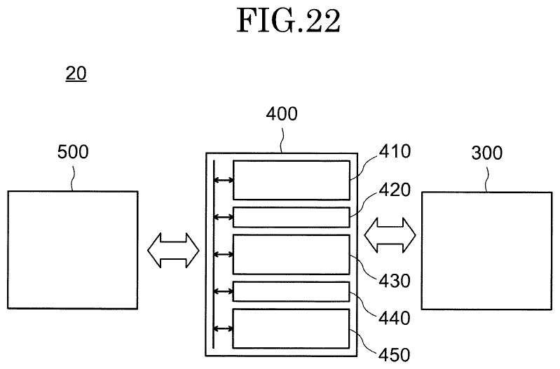

FIG. 22 is a schematic diagram of a memory system according to an embodiment of the present invention. As shown in FIG. 22, the memory system 20 includes the memory chip 300 and a memory controller 400. The memory controller 400 communicates with a host 500 and controls the memory chip 300 based on an instruction from the host 500.

The memory controller 400 includes a logical-physical conversion table 410, an MPU 420, an operation count storage unit 430, an ECC circuit 440, and an error-rate storage unit 450. The logical-physical conversion table 410 stores a logical address included in the instruction received from the host 500 and a physical address assigned to each page of the memory cell array 310 in association with each other. The operation count storage unit 430 stores the physical address corresponding to the memory block MBi or a page and the number of program operation, read operations, or erase operation executed on the memory block MBi or the page in association with each other. The ECC circuit 440 detects an error in the data read from the memory chip 300, and corrects the data when there is an error in the data. The error-rate storage unit 450 stores the physical address corresponding to the memory block MBi or the page and a bit error rate corresponding to the memory block MBi or the page in association with each other. The bit error rate may be an average value of the calculated bit error rates for each page, or may be a maximum value thereof. The MPU 420 controls the memory chip 300 in cooperation with the logical-physical conversion table 410, the operation count storage unit 430, the ECC circuit 440, and the error-rate storage unit 450. The memory controller 400 or the MPU 420 may be referred to as a control circuit. In this case, it can be said that the control circuit controls the memory cell array 310.

### 2-3. Operation of Memory System 20

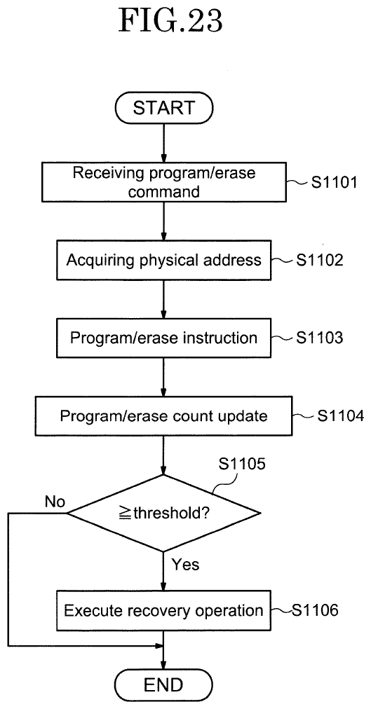

FIG. 23 is a flowchart showing a recovery operation of the memory system according to an embodiment of the present invention. Each step in the flowchart shown in FIG. 23 is executed by the logical-physical conversion table 410, the MPU 420, the operation count storage unit 430, the ECC circuit 440, and the error-rate storage unit 450 of the memory controller 400 cooperating with each other.

First, when the memory controller 400 receives a program instruction or an erase instruction from the host 500 (step S1101; program/erase command), the MPU 420 acquires a physical address corresponding to the memory block MBi or page to be programmed or erased based on the logical address specified by the instruction (step S1102; acquiring physical address). Next, the MPU 420 transmits the acquired physical address and program instruction or erase instruction to the memory chip 300, and executes the program operation or erase operation (step S1103; program/erase instruction). Next, the MPU 420 refers to the operation count storage unit 430 and updates the program count or erase count of the memory block MBi or page corresponding to the physical address where the operations described above have been executed (step S1104; program/erase count update).

Subsequently, the MPU 420 refers to the updated operation count storage unit 430 and determines whether the execution count of the program operation or the erase operation for the updated memory block MBi or page (the memory cell included in the page) has reached a predetermined number (threshold) (step S1105; ≥threshold?). When it is determined in S1105 that the execution count has reached the threshold value (“Yes” in S1105), the MPU 420 causes the memory chip 300 to execute the recovery operation described in the first embodiment (step S1106; execute recovery operation). On the other hand, if the execution count is less than the threshold value in S1105 (“No” in S1105), the MPU 420 ends the flowchart of FIG. 23.

The recovery operation is a voltage supply operation of applying the first voltage of a first polarity and the second voltage of a second polarity opposite to the first polarity to the ferroelectric layer 220. In FIG. 16 of the first embodiment, the first polarity is a positive polarity and the first voltage is the positive pulse voltage. In the positive polarity, a pulse voltage of 3 V, which is greater than the maximum voltage (2.5 V) in the program operation, is supplied. On the other hand, in FIG. 16, the second polarity is a negative polarity, and the second voltage is the negative pulse voltage. In the negative polarity, a pulse voltage of −2 V, which is greater than the maximum voltage (−1.5 V) in the erase operation, is supplied. In addition, the magnitude relationship of the voltages in the positive polarity or the negative polarity described above means the magnitude relationship of the absolute values of the voltages in each operation. That is, if a negative voltage (e.g., −2.5 V) is applied in the program operation and a positive voltage (e.g., 1.5 V) is applied in the erase operation, the first polarity is negative, the first voltage is a negative pulse voltage, a pulse voltage of −3 V is supplied as the first voltage of the first polarity, and a pulse voltage of 2 V is supplied as the second voltage of the second polarity.

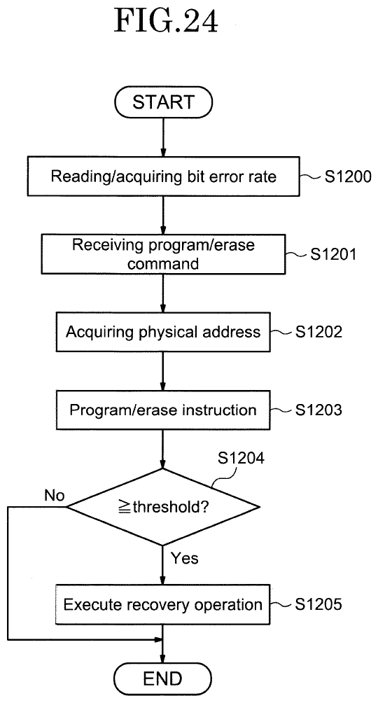

FIG. 24 is a flowchart showing a recovery operation of the memory system according to an embodiment of the present invention. Similar to each step in FIG. 23, each step in the flowchart shown in FIG. 24 is executed by the logical-physical conversion table 410, the MPU 420, the operation count storage unit 430, the ECC circuit 440, and the error-rate storage unit 450 of the memory controller 400 cooperating with each other.

Since steps S1201 to S1203 in the flowchart of FIG. 24 are the same as S1101 to S1103 of FIG. 23, the explanation thereof will be omitted. However, in the read operation before S1201 to S1203, the MPU 420 transmits the data received from the memory chip 300 to the ECC circuit 440 and acquires the bit error rate of the data (step S1200; reading/acquiring bit error rate). The ECC circuit 440 causes the error-rate storage unit 450 to store the acquired bit error rate in association with an appropriate physical address.

After S1203, the MPU 420 refers to the error-rate storage unit 450 after executing the program operation or the erase operation, and determines whether the bit error rate of the memory block MBi or the page on which the program operation or the erase operation has been performed has reached a predetermined probability (threshold) (step S1204; ≥threshold?). When it is determined in S1204 that the bit error rate has reached the threshold (“Yes” in S1204), the MPU 420 causes the memory chip 300 to execute the recovery operation described in the first embodiment (step S1205; execute recovery operation). On the other hand, if the bit error rate is less than the threshold value in S1204 (“No” in S1204), the MPU 420 ends the flowchart of FIG. 24.

### 3. Third Embodiment

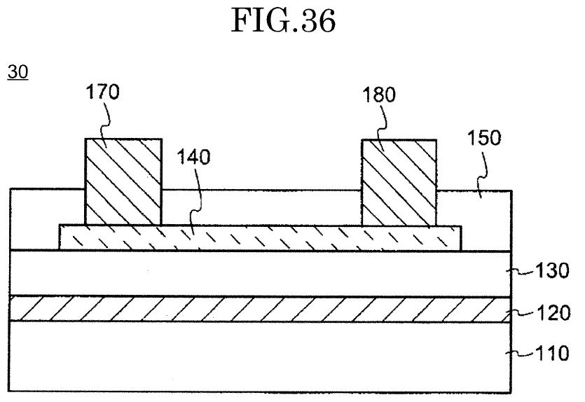

A configuration of the memory device 10 according to an embodiment of the present invention will be described with reference to FIG. 36. In the following embodiments, similar to the first embodiment, a memory device 30 in which a ferroelectric layer is used as a layer having a memory function is exemplified. The memory device 30 is the FeFET in which the oxide semiconductor layer is used as the layer functioning as the channel.

FIG. 36 is a schematic cross-sectional view showing the FeFET according to an embodiment of the present invention. As shown in FIG. 36, the memory device 30 includes a substrate 110, a gate electrode 120, a ferroelectric layer 130, a channel layer 140, a protective insulating layer 150, a source electrode 170, and a drain electrode 180. The gate electrode 120 is provided on the substrate 110. The channel layer 140 is provided at a position facing the gate electrode 120. The ferroelectric layer 130 is provided between the gate electrode 120 and the channel layer 140. The protective insulating layer 150 is provided on the channel layer 140 to cover a pattern end of the channel layer 140. An opening that reaches the channel layer 140 is provided in the protective insulating layer 150. The source electrode 170 and the drain electrode 180 are provided in the opening.

A semiconductor substrate or an insulating substrate is used as the substrate 110. For example, a silicone substrate or an SOI substrate is used as the semiconductor substrate. For example, a glass substrate or a quartz substrate is used as the insulating substrate. A general metal material is used as the gate electrode 120, the source electrode 170, and the drain electrode 180. For example, materials such as molybdenum, tungsten, titanium, and aluminum are used as the gate electrode 120, the source electrode 170, and the drain electrode 180.

For example, HZO can be used as the ferroelectric layer 130. A layer containing at least one of silicon, magnesium, aluminum, barium, zirconium, gadolinium, lanthanum, samarium, nitrogen, and yttrium in addition to hafnium and oxygen may be used as the ferroelectric layer 130. Furthermore, in order to suppress diffusion of impurities contained in the substrate 110 into the channel layer 140, a barrier layer that suppresses diffusion of the impurities may be provided between the substrate 110 and the ferroelectric layer 130. For example, silicon nitride may be used as the barrier layer.

An oxide semiconductor is used as the channel layer 140. An oxide semiconductor (IGZO) containing indium, gallium, and zinc, an oxide semiconductor (ITZO) containing indium, tin, and zinc, an oxide semiconductor (IZO) containing indium and zinc, an oxide semiconductor (ITO) containing indium and tin, or an indium oxide is used as the oxide semiconductor.

A general insulating material is used as the protective insulating layer 150. For example, an inorganic insulating layer such as silicon oxide, silicon nitride, aluminum oxide, and aluminum nitride is used as the protective insulating layer 150. An organic insulating layer, such as a polyimide substrate, an acryl substrate, a siloxane substrate, and a fluororesin substrate, may be used as the protective insulating layer 150. The protective insulating layer 150 may have a structure in which the above materials are stacked.

In the memory device 30 shown in FIG. 36, the thickness of the ferroelectric layer 130 can be made larger than 1 nm and smaller than 30 nm. When the thickness of the ferroelectric layer 130 falls within the above range, the same low-voltage operation as the low-voltage operation with respect to the memory device 10 of the first embodiment can be performed. As a result, even when the MW is narrowed by the cyclic operations with respect to r the memory device 30, the MW can be recovered by the recovery operation described in the first embodiment. In addition, to ensure the polarization characteristics (ferroelectric characteristics) of the ferroelectric layer 130, the thickness of the ferroelectric layer 130 may be larger than 3 nm. Furthermore, by making the thickness of the ferroelectric layer 130 larger than 4 nm and smaller than 15 nm, similar to the case where the thickness of the ferroelectric layer 220 is 4.6 nm or more and 6 nm or less in the first embodiment, good endurance characteristics after the recovery operation can be obtained.

### 4. Fourth Embodiment

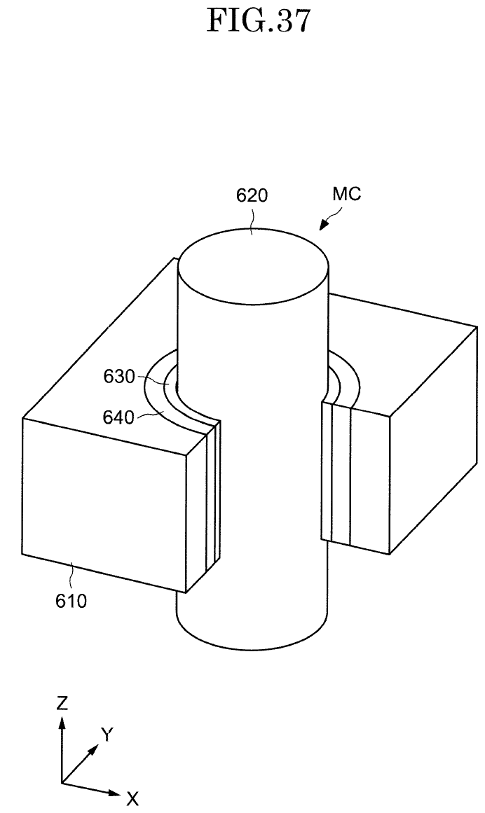

The FeFET having a different configuration from the above embodiment will be described with reference to FIG. 37. In the first embodiment and the third embodiment, a horizontal FeFET in which a current flows in a direction parallel to the main surface of the substrate has been exemplified, but in the present embodiment, a vertical FeFET will be described.

FIG. 37 is a perspective view showing a configuration of a memory cell according to an embodiment of the present invention. As shown in FIG. 37, the memory cell MC includes a conductive layer 610, a semiconductor layer 620, an oxide insulating layer 630, and a ferroelectric layer 640. The conductive layer 610 is formed along the main surface of the substrate. That is, the conductive layer 610 extends in the XY plane. The conductive layer 610 is stacked in a direction Z. The two conductive layers 610 adjacent in the direction Z are separated by an insulating layer (not shown). That is, the conductive layer 610 and the insulating layer are alternately stacked on the substrate.

The semiconductor layer 620 is provided inside a memory hole that penetrates the stacked conductive layer 610 and the insulating layer. The semiconductor layer 620 may be columnar or cylindrical. Although FIG. 37 exemplifies a configuration in which the semiconductor layer 620 is cylindrical, the semiconductor layer 620 may be polygonal or frustoconical. In the case where the semiconductor layer 620 is cylindrical, a cylindrical hollow is filled with fillers such as silicone oxide. The oxide insulating layer 630 is provided around the semiconductor layer 620. The ferroelectric layer 640 is provided around the oxide insulating layer 630. The oxide insulating layer 630 is in contact with the semiconductor layer 620 and the ferroelectric layer 640 is in contact with the oxide insulating layer 630 and the conductive layer 610. In addition, other layers may be provided between the semiconductor layer 620 and the oxide insulating layer 630. Another layer may be provided between the oxide insulating layer 630 and the ferroelectric layer 640. Another layer may be provided between the ferroelectric layer 640 and the conductive layer 610.

In the above configuration, the semiconductor layer 620 functions as a channel. The conductive layer 610 functions as a gate electrode. The oxide insulating layer 630 and the ferroelectric layer 640 function as a gate insulating layer. That is, when a voltage is applied to the conductive layer 610, an electric field is formed in the semiconductor layer 620 via the oxide insulating layer 630 and the ferroelectric layer 640, and carriers are generated in the semiconductor layer 620 by the electric field. By generating a potential difference between both ends of the semiconductor layer 620 in the direction Z, carriers generated by the electric field move in the direction Z. That is, the memory cell MC is a vertical FeFET that allows current to flow in the vertical direction (direction Z).

In contrast to FIG. 1 and FIG. 37, the conductive layer 610 corresponds to the gate electrode 230. The semiconductor layer 620 corresponds to the semiconductor layer 200. The oxide insulating layer 630 corresponds to the oxide insulating layer 210. The ferroelectric layer 640 corresponds to the ferroelectric layer 220. Therefore, the memory cell MC operates in the same manner as the memory device 10.

The plurality of the memory cells MC is provided along the pillar-shaped semiconductor layer 620 in the direction Z. That is, the plurality of memory cells MC is connected in series along the semiconductor layer 620.

### 5. Fifth Embodiment

Hereinafter, research results related to an embodiment of the present invention will be described.

### [Title]

HZO Scaling and Fatigue Recovery in FeFET with Low Voltage Operation: Evidence of Transition from Interface Degradation to Ferroelectric Fatigue

Thickness scaling of FeFETs with Hf_{0.5}Zr_{0.5}O₂ (HZO) from 11 down to 4.6 nm is systematically studied in this work in terms of the memory characteristics and the memory window (MW) narrowing mechanism. The HZO thickness scaling leads to low-voltage operation, higher Iₒₙ/I_{off} ratio, lower S.S., and better endurance. It is also found, for the first time, that with reducing a cycling voltage, the dominant narrowing mechanism changes from MOS interface degradation to ferroelectric fatigue, which can be recovered by a high-voltage pulse. Based on this finding, we propose and demonstrate a method to improve endurance by utilizing this recovery, which is more effective in thinner HZO FeFETs.

### INTRODUCTION

An HZO-based FeFET has been recognized as a promising candidate for non-volatile memory, logic, and AI accelerators. However, several challenges including high-voltage operation and low endurance (typically <10⁵) greatly impede their applications. In MFM capacitors for FeRAM, HZO thickness scaling has been proven to be an efficient approach for both reducing voltage and improving endurance. Moreover, the degradation due to fatigue in MFM capacitors can be recovered, further improving endurance. However, in FeFETs, systematic studies regarding the impact of HZO thickness scaling on device characteristics and the understanding of MW narrowing are still lacking. In this work, we systematically study the memory characteristics of FeFETs with HZO thickness ranging from 11 to 4.6 nm with an emphasis on low-voltage operation and examine the degradation mechanism of MW. We have newly found the recovery of MW in FeFETs under low-voltage operation. Better endurance can be achieved by the thickness scaling and this fatigue recovery.

### [Device Fabrication]

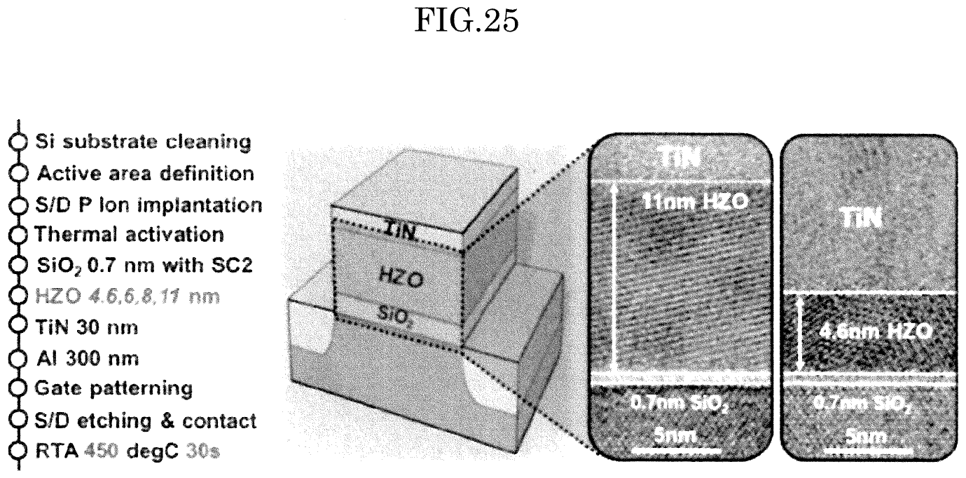

FIG. 25 shows the process flow and TEM images of TIN/HZO/SiO₂ FeFETs, employed in this study. The thicknesses of ALD HZO are 11 nm, 8 nm, 6 nm, and 4.6 nm. RTA temperature was set at 450° C. to obtain the optimum interface quality and ferroelectricity in thin HZO.

### [Low-Voltage Operation]

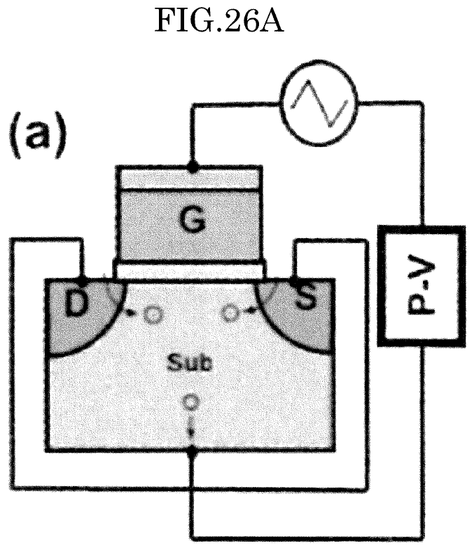

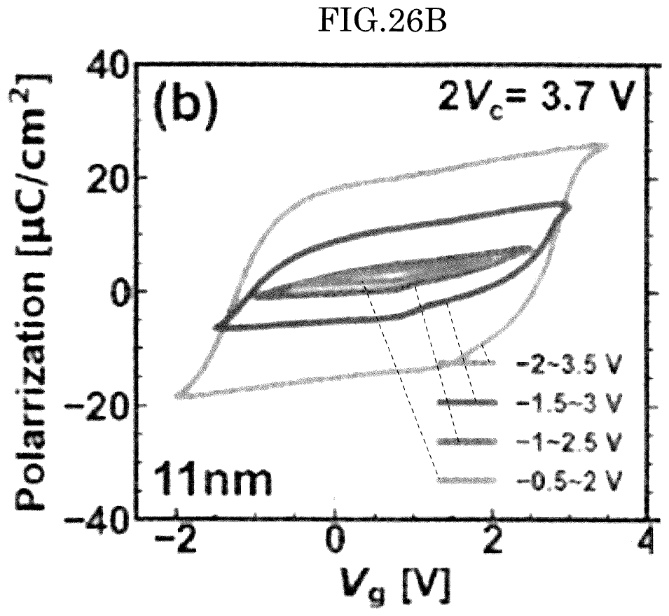

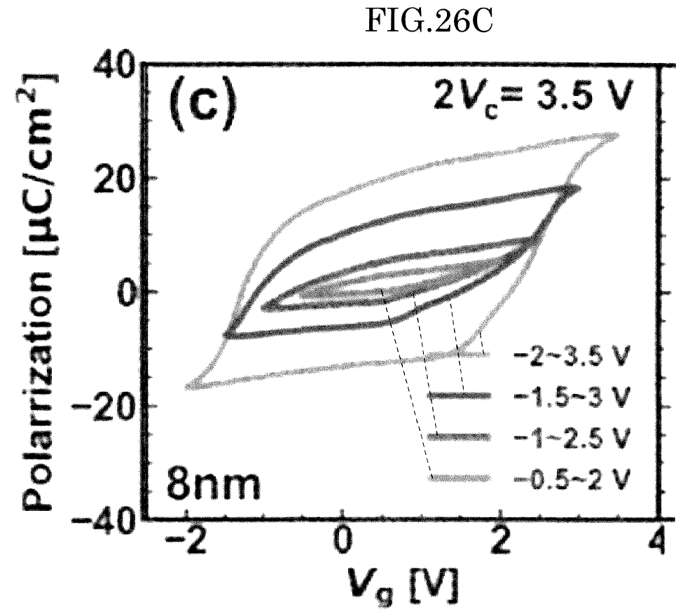

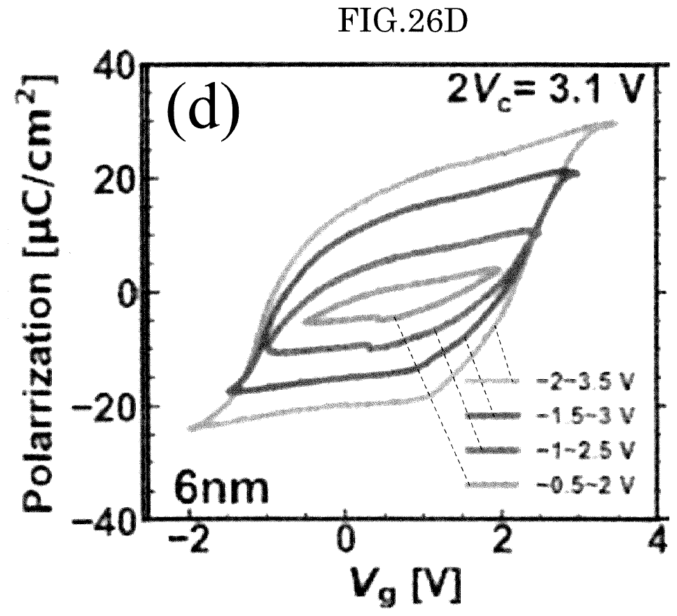

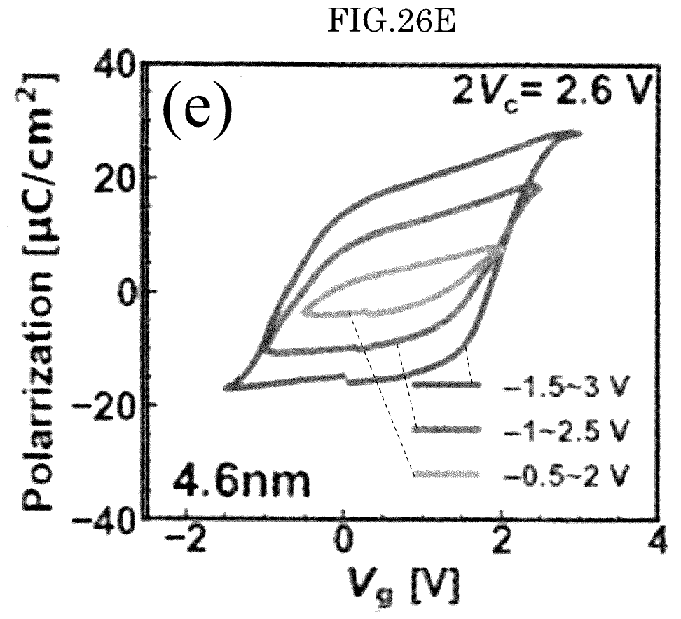

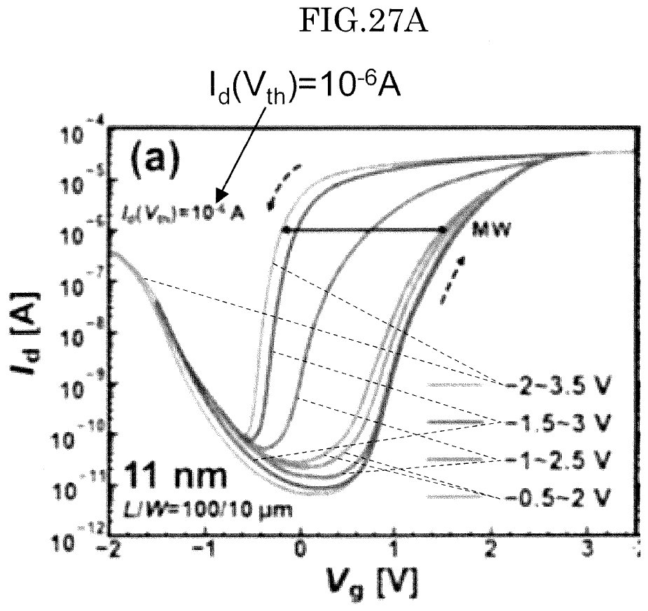

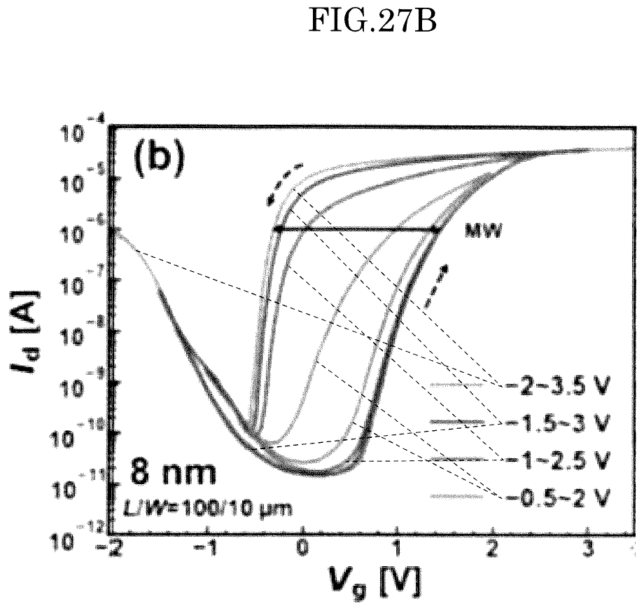

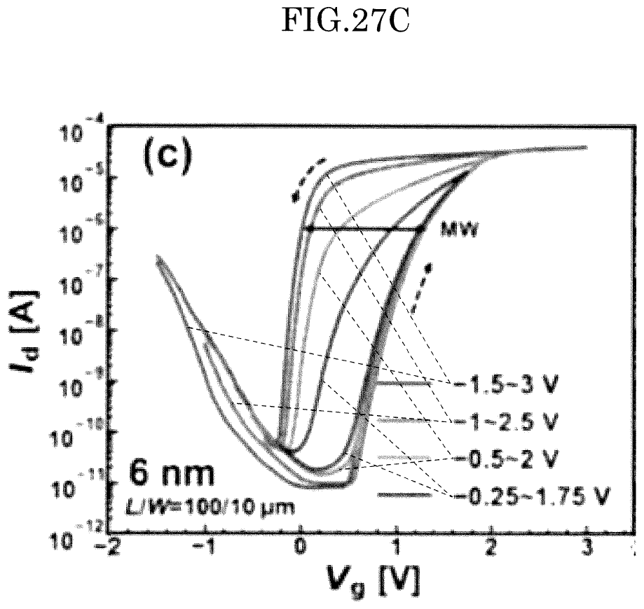

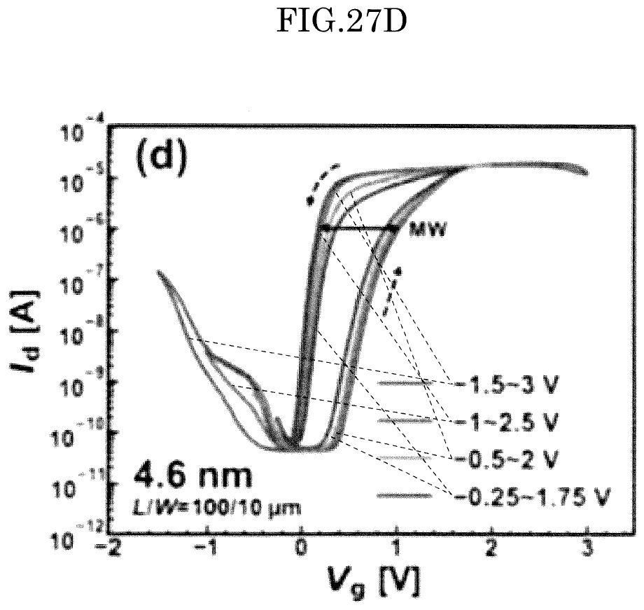

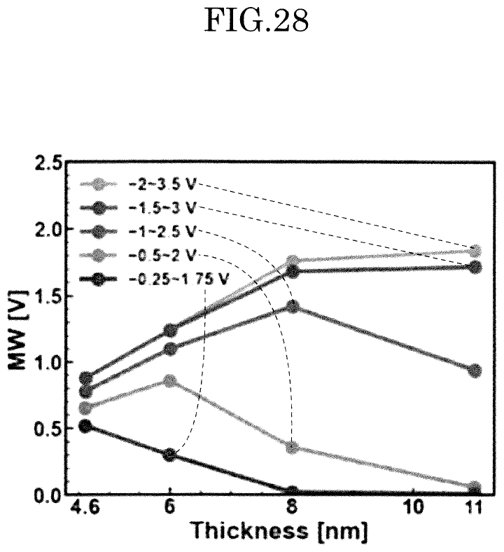

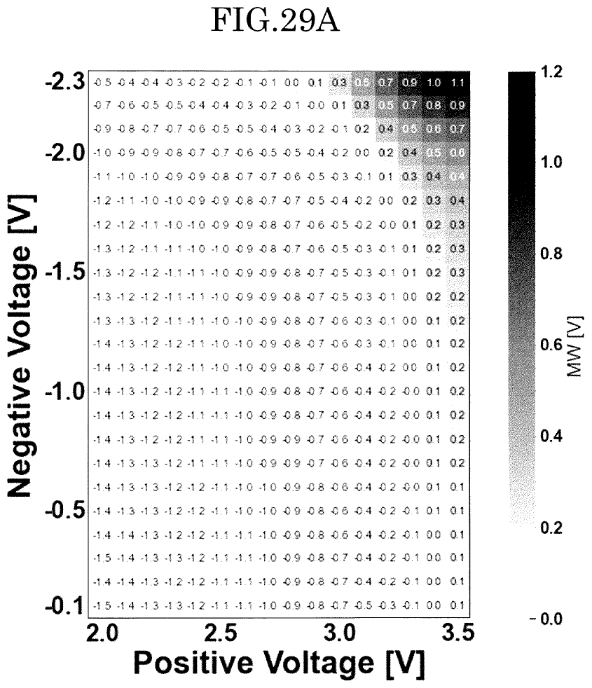

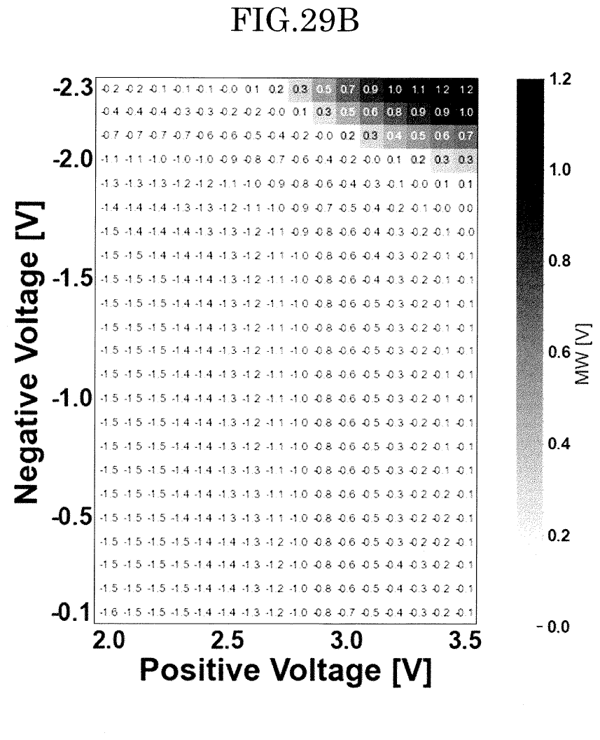

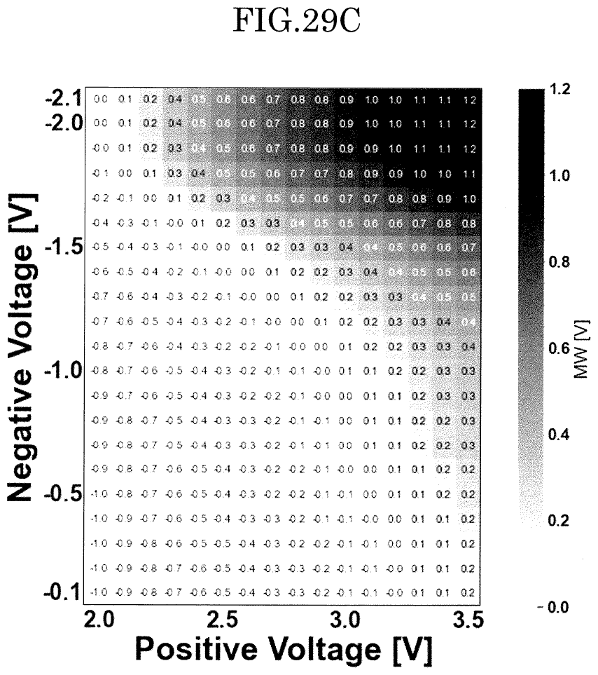

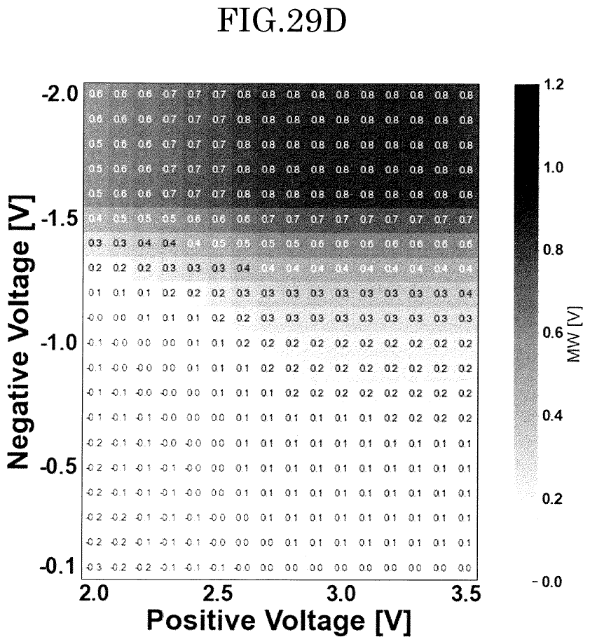

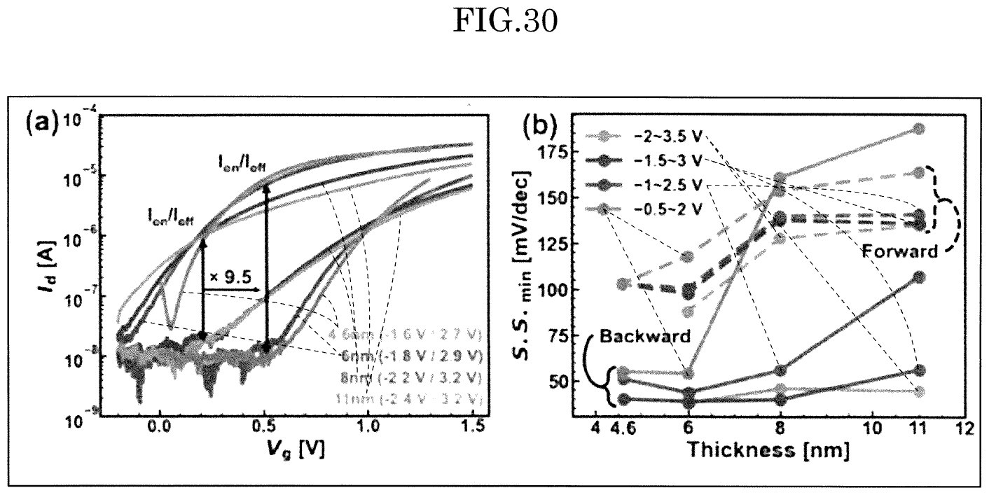

FIG. 26A shows the measurement setup of P—V measurements directly on FeFETs. The results in FIG. 26B to FIG. 26E show that thinner HZO films provide lower V_{c}, which is beneficial for low-voltage operation, as seen from higher 2Pᵣ, in thinner films for the same voltage range. The I_{d}-V_{g} characteristics (FIG. 27A to FIG. 27D) and extracted MWs (FIG. 28) indicate that even in low V_{g} ranges of −0.5 V/2 V, the 6 nm and 4.6 nm FeFETs have MWs of 0.7 V and 0.8 V, respectively, larger than those of 0.3 V and 0.05 V in 11 nm and 8 nm, respectively. FIG. 29A to FIG. 29D show the MW mapping determined from Vth under the program/erase pulse of 1 μs and fast I_{d}-V_{g} measurements, clearly illustrating that thinner HZO FeFETs can operate with lower voltages. FIG. 30(a) compares the I_{d}-V_{g} curves of FeFETs with the 4 different HZO thicknesses under MW of 0.8 V. The erasing/programming pulse voltages are reduced from −2.4 V/3.2 V (11 nm) to −1.6 V/2.7 V (4.6 nm). It is found, moreover, that the thinner HZO FeFETs show a higher Iₒₙ/I_{off} ratio at the same MW, which is 9.5× higher in the 4.6 nm HZO FeFET than in the 11 nm one, due to the lower S. S. values (FIG. 30(b)).

### [Endurance Properties]

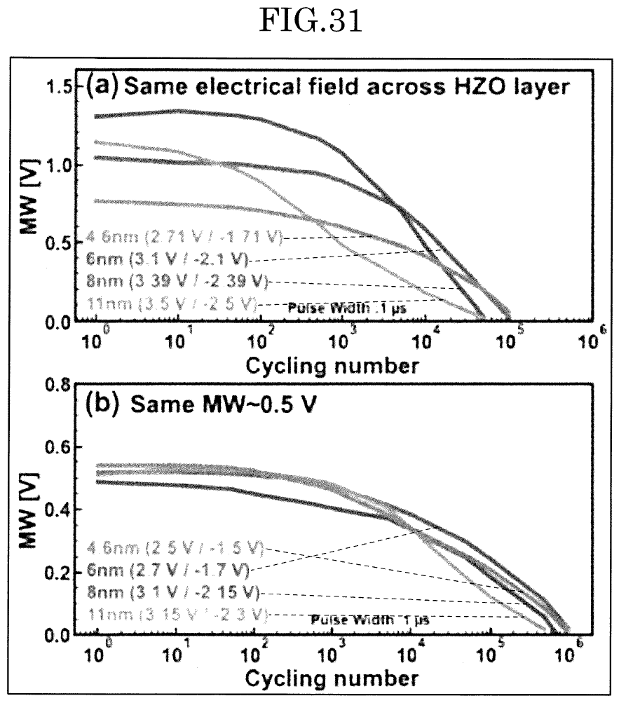

FIG. 31 shows the endurance characteristics of FeFETs with different HZO thicknesses under (a) the same electric field and (b) the same memory window of 0.5 V. Under the same electric field, the 6 nm and 4.6 nm thick HZO FeFETs exhibit almost two times better endurance (to 10⁵) than the 11 nm thick ones (5×10⁴). Also, under the same MW of 0.5 V, the endurance of the 6 nm and 4.6 nm HZO FeFETs reaches 1×10⁶, which is higher than that of the 11 nm device. These results indicate that HZO scaling leads to an improvement in the endurance of FeFETs.

### [MW Narrowing Mechanisms and Fatigue Recovery]

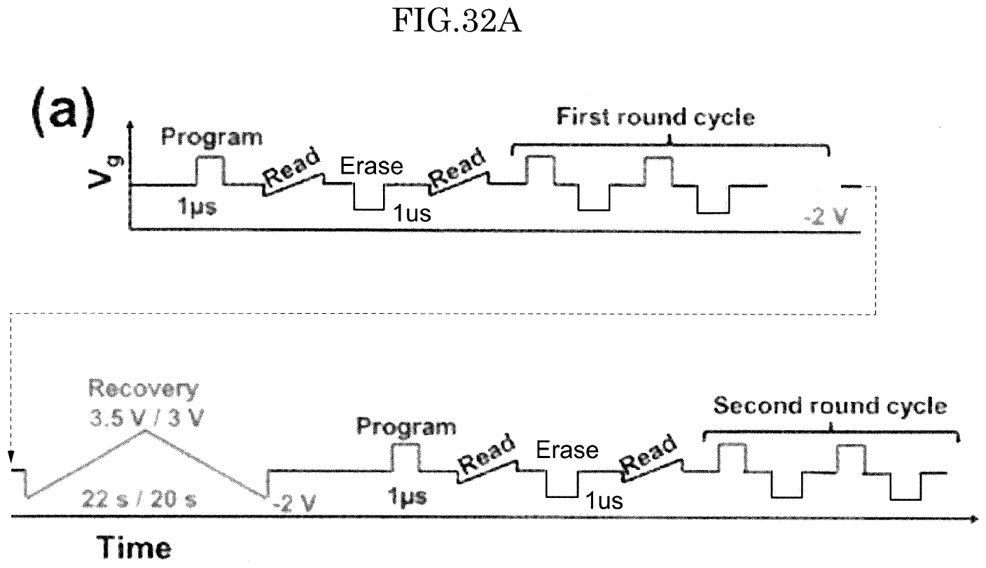

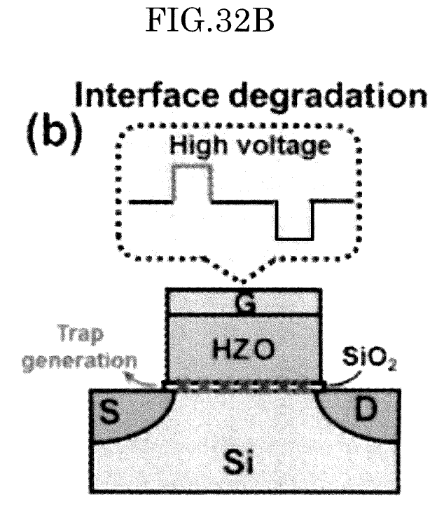

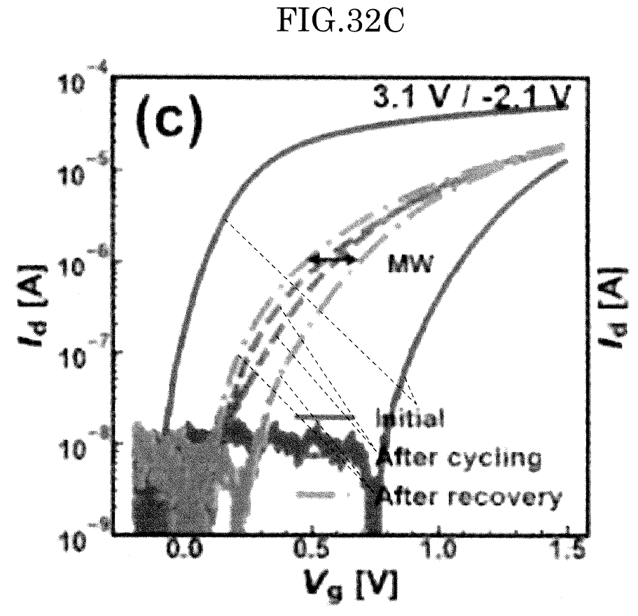

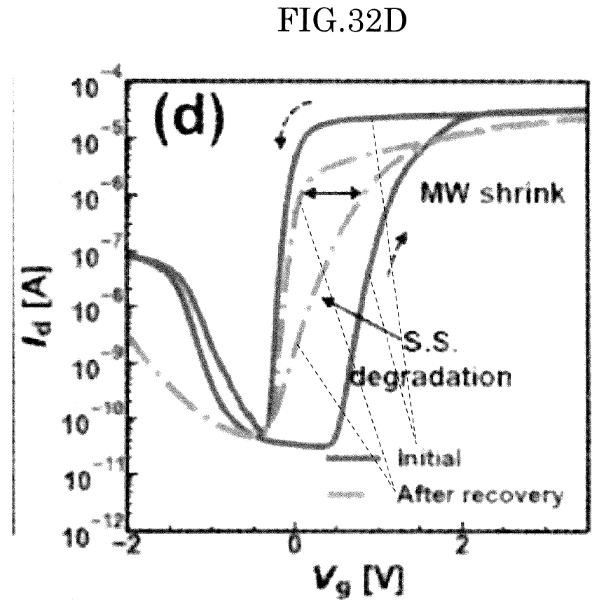

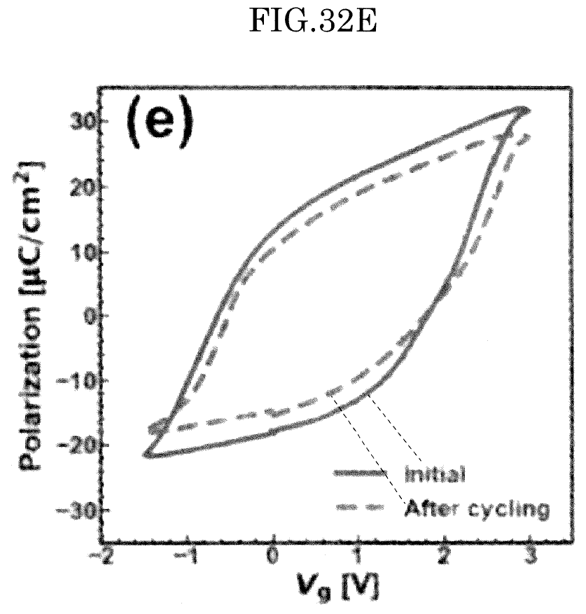

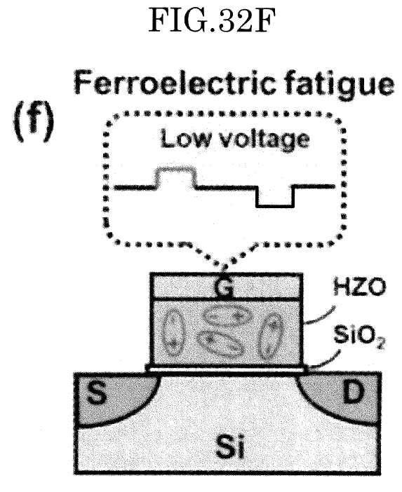

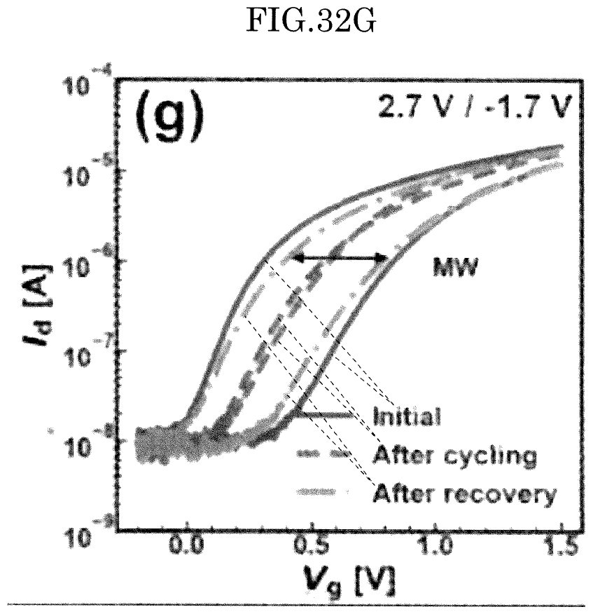

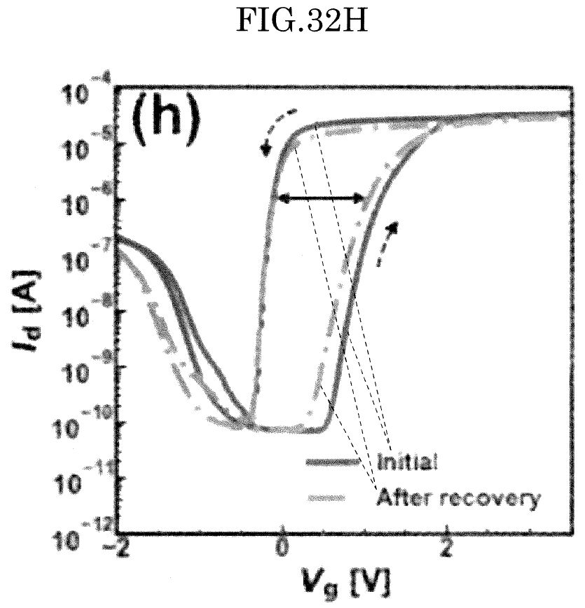

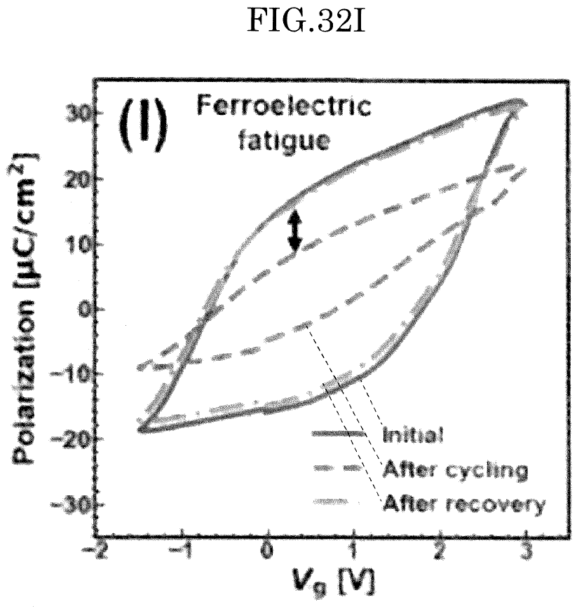

The MW narrowing of FeFETs has been conventionally attributed to MOS interface degradation, which becomes worse with higher operating voltage. In this study, we have newly identified another mechanism causing MW narrowing in FeFETs: ferroelectric fatigue brought by low operating voltage, which should be discriminated from interface degradation by high voltage, as illustrated in FIG. 32B and FIG. 32F. Here, we performed P—V measurements on FeFETs to evaluate the polarization properties in addition to conventional I_{d}-V_{g}, measurements. It is found from the fast and DC I_{d}-V_{g} under the high voltage, shown in FIG. 32C and FIG. 32D, and those under the low voltage (FIG. 32G and FIG. 32H) that MW decreases and S.S. degrades significantly after cycling. On the other hand, P—V in FIG. 32E and FIG. 32I indicates that the ferroelectric polarization decreases dramatically after low-voltage cycling, whereas the polarization does not decrease after high-voltage cycling. These results strongly indicate that MW narrowing by low-voltage cycling is caused by a decrease in polarization due to ferroelectric fatigue, while MW narrowing by high-voltage cycling is due to MOS interface degradation.

Moreover, we have found that the MW narrowing of FeFETs due to this ferroelectric fatigue can be recovered by high V_{g} signals in a similar way to MFM capacitors, whereas the MW narrowing due to interface degradation cannot be recovered. Here, long-term triangular signals were applied to recover the degraded FeFETs, as shown in FIG. 32A. It is found that MWs and polarization properties are significantly recovered in FeFETs after low-voltage cycling (FIG. 32G to FIG. 32I), strongly supporting that ferroelectric fatigue is recoverable. In contrast, the small MW and degraded S. S. are still observed after the recovery pulse for high-voltage cycling (FIG. 32C and FIG. 32D), indicating that the interface degradation is irrecoverable. As a result, it is concluded that the MW narrowing has two different mechanisms, interface degradation under high-voltage cycling and ferroelectric fatigue under low-voltage cycling, which occur at different locations inside FeFETs (inside the ferroelectric film or at the interface). This fact also suggests that we can utilize recovery pulses to regain MW for FeFETs with ferroelectric fatigue.

### [Endurance Improvement Utilizing Fatigue Recovery]

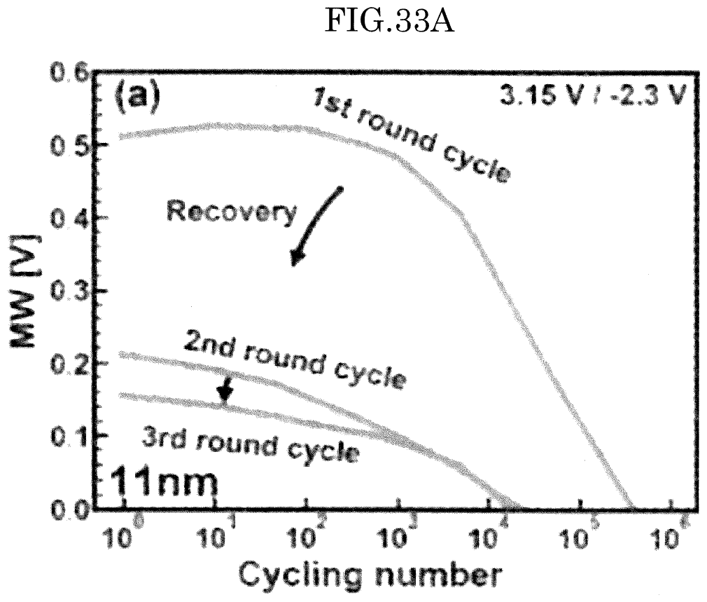

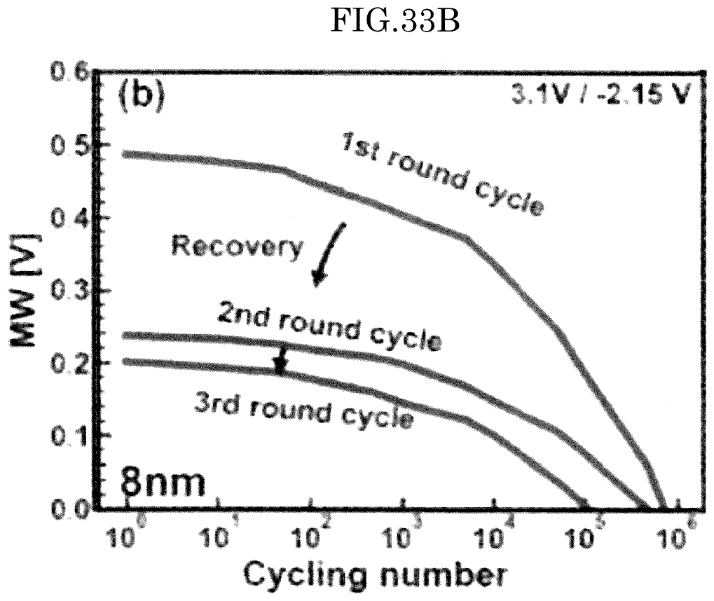

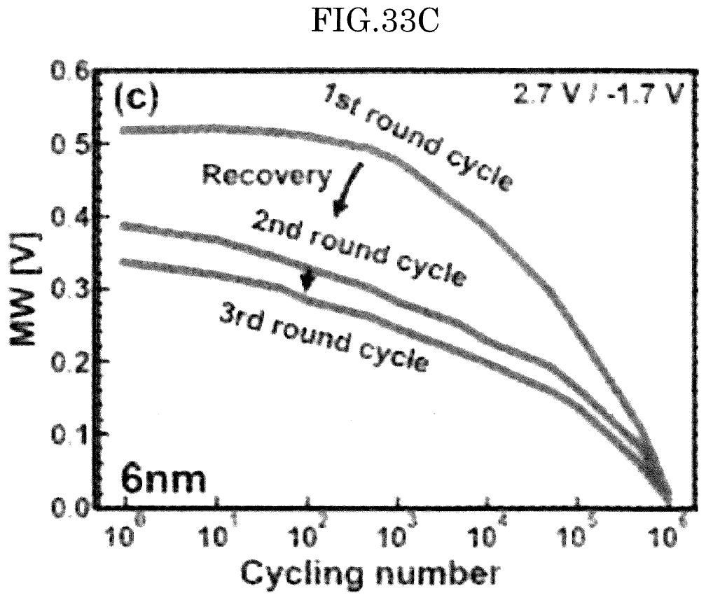

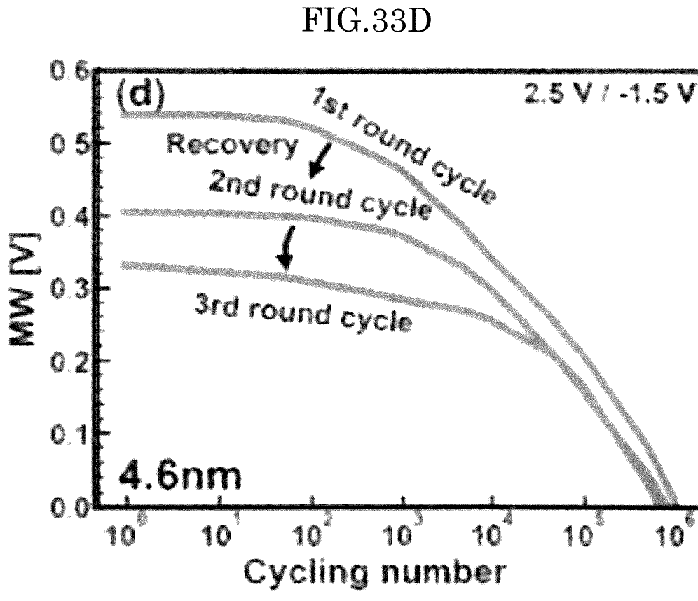

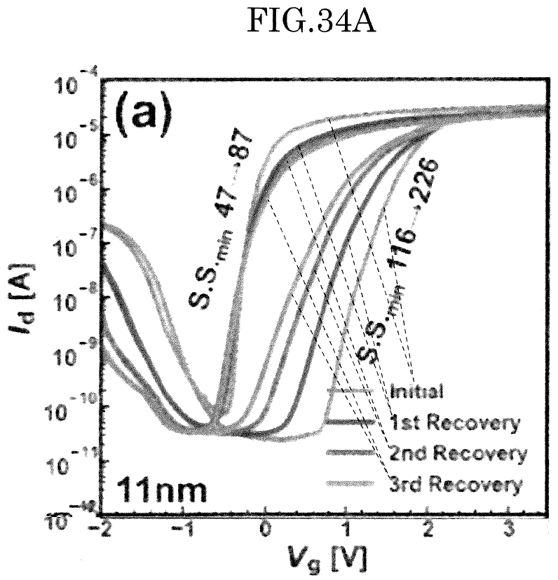

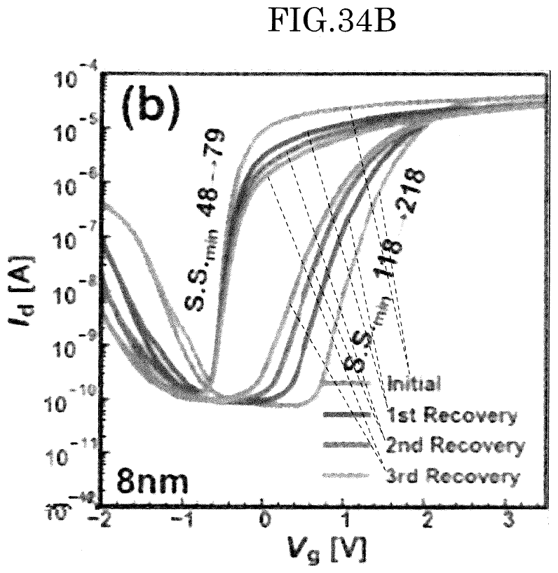

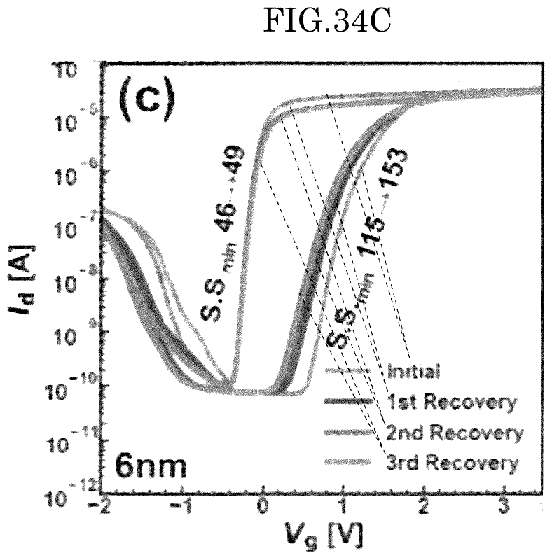

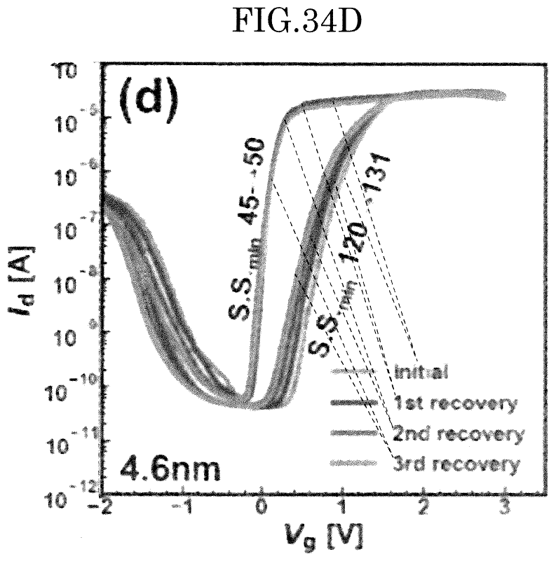

FIG. 33A to FIG. 33D shows the endurance characteristics of FeFETs with fixed initial MW after repeated recovery pulses. It is found that 6 nm and 4.6 nm HZO FeFETs have significant recovery after 1st and 2nd recovery pulses, leading to the endurance of 10⁶ cycles in the 2nd and 3rd cycling. In contrast, the 11 nm and 8 nm HZO FeFETs show weaker recovery like MW less than 0.25 V after the recovery pulse and the cycling number far less than 10⁶. This difference can be caused by more severe degradation of the MOS interfaces in the thicker HZO FeFETs (FIG. 34A to FIG. 34D). Here, the S. S. and MW are found to degrade more significantly in the thicker FeFETs. As the electric field in HZO is estimated to be lower in the thicker HZO FeFETs at fixed MW, more severe degradation in the thicker FeFETs is attributable to higher voltage operation. Note that much higher endurance is expected by applying the proposed method to FeFETs with further improved interfaces.

### [Conclusion]

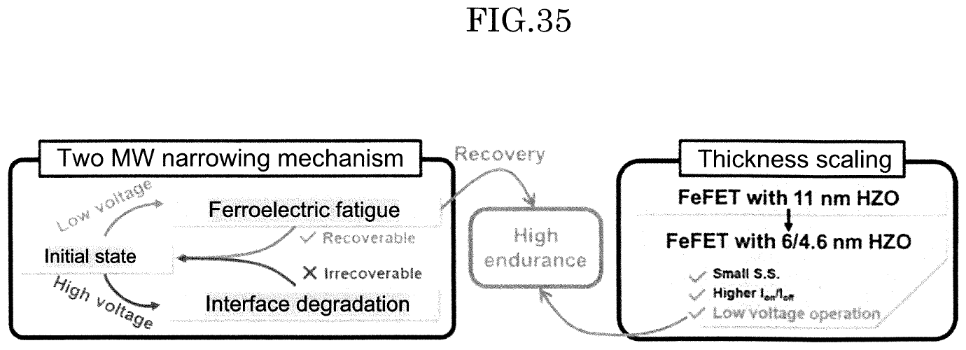

This work is summarized in FIG. 35. The thickness scaling can realize not only the low-voltage operation but also improvement of the Iₒₙ/I_{off} ratio and endurance. Moreover, for the first time, we have proven that, with reducing Vg, the MW narrowing mechanism changes from irrecoverable MOS interface degradation to recoverable ferroelectric fatigue. Based on this finding, we have purposed and demonstrated a way of improving endurance by utilizing this recovery property of MW.

As shown in FIG. 35, ferroelectric fatigue and the interface degradation were found to be the dominant MW narrowing mechanism for the low-voltage cycle and the high-voltage cycle, respectively. In addition, ferroelectric fatigue was found to be recoverable, which leads to a newly proposed method for FeFET recovery. Furthermore, the low-voltage operation afforded by HZO thickness scaling is shown. The combination of these two strategies, based on the low-voltage operation of FeFET, effectively contributes to the high endurance characteristics.

### 6. Sixth Embodiment

Hereinafter, a configuration related to an embodiment of the present invention will be described. A configuration according to the sixth embodiment can be described as a scope of the claims.

### [Constituent Features 1]

A ferroelectric memory device comprising:
a channel layer containing silicon;
an interface layer in contact with the channel layer;
a ferroelectric layer in contact with the interface layer, the ferroelectric layer containing hafnium oxide; and
a gate electrode facing the channel layer via the ferroelectric layer and the interface layer,
wherein a thickness of the ferroelectric layer is less than 7 nm and more than 3 nm.

### [Constituent Features 2]

The ferroelectric memory device according to Structure 1,
wherein the thickness of the ferroelectric layer is equal to or less than 6 nm and equal to or more than 4.6 nm.

### [Constituent Features 3]

The ferroelectric memory device according to Structure 1,
wherein the interface layer comprises silicon oxide.

### [Constituent Features 4]

The ferroelectric memory device according to Structure 1,
wherein a thickness of the interface layer is less than 5 nm.

### [Constituent Features 5]

The ferroelectric memory device according to Structure 1,
wherein the ferroelectric layer comprises hafnium (Hf), oxygen (O), and at least one of silicon (Si), magnesium (Mg), aluminum (Al), barium (Ba), zirconium (Zr), gadolinium (Gd), lanthanum (La), samarium (Sm), nitrogen (N) and yttrium (Y).

### [Constituent Features 6]

A semiconductor memory device comprising:
a memory cell containing a ferroelectric memory device according to Structure 1, and
a control circuit controlling the memory cell,
   wherein the control circuit determines whether a number of times of executions of a program operation or an erase operation on the memory cell is a predetermined number,
   if the number of times of executions is the predetermined number, executing a voltage application process in which a first voltage of a first polarity and a second voltage of a second polarity opposite to the first polarity are applied to the ferroelectric layer, and
the first voltage is larger than a maximum voltage applied in the program operation and the second voltage is larger than a maximum voltage applied in the erase operation.

### [Constituent Features 7]

A semiconductor memory device comprising:
a plurality of memory cells containing a ferroelectric memory device according to Structure 1, and
a control circuit controlling the plurality of memory cells,
   wherein the control circuit determines whether a bit error rate of data read from the plurality of memory cells is a predetermined rate or more,
   if the bit error rate is the predetermined rate or more, executing a voltage application process in which a first voltage of a first polarity and a second voltage of a second polarity opposite to the first polarity are applied to the ferroelectric layer, and
the first voltage is larger than a maximum voltage applied in the program operation and the second voltage is larger than a maximum voltage applied in the erase operation.

### [Constituent Features 8]

A ferroelectric memory device comprising:
a channel layer containing a metal oxide;
a ferroelectric layer in contact with the channel layer, the ferroelectric layer containing hafnium oxide; and
a gate electrode facing the channel layer via the ferroelectric layer,
wherein a thickness of the ferroelectric layer is less than 30 nm and more than 1 nm.

### [Constituent Features 9]

The ferroelectric memory device according to Structure 8,
wherein the thickness of the ferroelectric layer is less than 15 nm and more than 4 nm.

### [Constituent Features 10]

The ferroelectric memory device according to Structure 8,
wherein the metal oxide is IGZO, ITZO, IZO, ITO or indium oxide.

### [Constituent Features 11]

The ferroelectric memory device according to Structure 8,
wherein the ferroelectric layer comprises hafnium (Hf), oxygen (O), and at least one of silicon (Si), magnesium (Mg), aluminum (Al), barium (Ba), zirconium (Zr), gadolinium (Gd), lanthanum (La), samarium (Sm), nitrogen (N) and yttrium (Y).

### [Constituent Features 12]

A semiconductor memory device comprising:
a memory cell containing a ferroelectric memory device according to Structure 8, and
a control circuit controlling the memory cell,
   wherein the control circuit determines whether a number of times of executions of a program operation or an erase operation on the memory cell is a predetermined number,
   if the number of times of executions is the predetermined number, executing a voltage application process in which a first voltage of a first polarity and a second voltage of a second polarity opposite to the first polarity are applied to the ferroelectric layer,
the first voltage is larger than a maximum voltage applied in the program operation, and
the second voltage is larger than a maximum voltage applied in the erase operation.

### [Constituent Features 13]

A semiconductor memory device comprising:
a plurality of memory cells containing a ferroelectric memory device according to Structure 8, and
a control circuit controlling the plurality of memory cells,
   wherein the control circuit determines whether a bit error rate of data read from the plurality of memory cells is a predetermined rate or more,
   if the bit error rate is the predetermined rate or more, executing a voltage application process in which a first voltage of a first polarity and a second voltage of a second polarity opposite to the first polarity are applied to the ferroelectric layer, and
the first voltage is larger than a maximum voltage applied in the program operation, and
the second voltage is larger than a maximum voltage applied in the erase operation.

Each of the embodiments (including modifications) described above as an embodiment of the present invention can be appropriately combined and implemented as long as no contradiction is caused. The addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A memory system comprising:
a memory cell array with memory cells including a memory device arranged in a matrix; and
a control circuit configured to control the memory cell array,
wherein
the memory device includes:
a semiconductor layer;
a gate electrode facing the semiconductor layer;
an insulating layer provided between the semiconductor layer and the gate electrode; and
a ferroelectric layer provided between the insulating layer and the gate electrode and containing hafnium oxide,
the semiconductor layer contains silicon,
the insulating layer is in contact with the semiconductor layer,
the ferroelectric layer is in contact with the insulating layer,
a thickness of the ferroelectric layer is greater than 3 nm and less than 7 nm,
when the control circuit determines:
whether a number of times of executions of a program operation or an erase operation on the memory cells reaches a predetermined number of times; or
whether bit error rate is a predetermined rate or more after executions of a program or an erase process on the memory cells,
the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more,
wherein
the first voltage is greater than a maximum voltage applied in the program operation, and the second voltage is greater than a maximum voltage applied in the erase operation,
in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and
when a pulse width of the first pulse voltage is set to a (μsec) and a pulse width of the second pulse voltage is set to b (μsec),
$$0.1 μsec ≦ a \times m < 250 μsec \qquad ( Equation 1 )$$
$$0.1 μsec ≦ b \times n < 250 μsec . \qquad ( Equation 2 )$$

2. The memory system according to claim 1, wherein a thickness of the ferroelectric layer is 4.6 nm or more and 6 nm or less.

3. The memory system according to claim 1, wherein the insulating layer contains silicon oxide.

4. The memory system according to claim 1, wherein a thickness of the insulating layer is less than 5 nm.

5. The memory system according to claim 1, wherein the ferroelectric layer contains, in addition to hafnium and oxygen, at least one of silicon, magnesium, aluminum, barium, zirconium, gadolinium, lanthanum, samarium, nitrogen, and yttrium.

6. A method for controlling a memory system comprising:
a memory cell array with memory cells including a memory device arranged in a matrix; and
a control circuit configured to control the memory cell array,
wherein
the memory device includes:
a semiconductor layer;
a gate electrode facing the semiconductor layer;
an insulating layer provided between the semiconductor layer and the gate electrode; and
a ferroelectric layer provided between the insulating layer and the gate electrode and containing hafnium oxide,
the semiconductor layer contains silicon,
the insulating layer is in contact with the semiconductor layer,
the ferroelectric layer is in contact with the insulating layer,
a thickness of the ferroelectric layer is greater than 3 nm and less than 7 nm,
when the control circuit determines:
whether a number of times of executions of a program operation or an erase operation on the memory cells reaches a predetermined number of times; or
whether a bit error rate is a predetermined rate or more,
the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more,
wherein
the first voltage is greater than a maximum voltage applied in the program operation, and the second voltage is greater than a maximum voltage applied in the erase operation,
in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and
when a pulse width of the first pulse voltage is set to a (μsec) and a pulse width of the second pulse voltage is set to b (μsec),
$$0.1 μsec ≦ a \times m < 250 μsec \qquad ( Equation 1 )$$
$$0.1 μsec ≦ b \times n < 250 μsec . \qquad ( Equation 2 )$$

7. The method for controlling a memory system according to claim 6, wherein waveforms of the first pulse voltage and the second pulse voltage are substantially rectangular.

8. The method for controlling a memory system according to claim 6, wherein the control circuit alternately applies the first pulse voltage and the second pulse voltage to the ferroelectric layer.

9. The method for controlling a memory system according to claim 6,
wherein
the first voltage is positive,
an absolute value of the first voltage is 3.0 V or more,
the second voltage is negative, and
an absolute value of the second voltage is 2.0 V or more.

10. A memory system comprising:
a plurality of memory cell arrays with a memory device arranged in a matrix; and
a control circuit configured to control the plurality of memory cell arrays,
wherein
the memory device includes:
an oxide semiconductor layer;
a gate electrode facing the oxide semiconductor layer; and
a ferroelectric layer provided between the oxide semiconductor layer and the gate electrode and containing hafnium oxide,
a thickness of the ferroelectric layer is greater than 1 nm and less than 30 nm,
when the control circuit determines:
whether a number of times of executions of a program operation or an erase operation on memory cells included in each of the plurality of memory cell arrays reaches a predetermined number of times, or
whether a bit error rate is a predetermined rate or more,
the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more,
wherein
the first voltage is greater than a maximum voltage applied in the program operation, and the second voltage is greater than a maximum voltage applied in the erase operation,
in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and
when a pulse width of the first pulse voltage is set to a (μsec) and a pulse width of the second pulse voltage is set to b (μsec),
$$0.1 μsec ≦ a \times m < 250 μsec \qquad ( Equation 1 )$$
$$0.1 μsec ≦ b \times n < 250 μsec . \qquad ( Equation 2 )$$

11. The memory system according to claim 10, wherein a thickness of the ferroelectric layer is greater than 4 nm and less than 15 nm.

12. The memory system according to claim 10, wherein the oxide semiconductor layer is IGZO, ITZO, IZO, ITO, or indium oxide.

13. The memory system according to claim 10, wherein the ferroelectric layer contains, in addition to hafnium and oxygen, at least one of silicon, magnesium, aluminum, barium, zirconium, gadolinium, lanthanum, samarium, nitrogen, and yttrium.

14. A method for controlling a memory system comprising:
a plurality of memory cell arrays with a memory device arranged in a matrix; and
a control circuit configured to control the plurality of memory cell arrays,
wherein
the memory device includes:
an oxide semiconductor layer;
a gate electrode facing the oxide semiconductor layer; and
a ferroelectric layer provided between the oxide semiconductor layer and the gate electrode and containing hafnium oxide,
a thickness of the ferroelectric layer is greater than 1 nm and less than 30 nm,
when the control circuit determines:
whether a number of times of executions of a program operation or an erase operation on the memory cell reaches a predetermined number of times; or
whether a bit error rate is a predetermined rate or more,
the control circuit executes a voltage application process in which a first voltage of a first polarity and a second voltage of a second polarity opposite to the first polarity are applied to the ferroelectric layer so that Equation 1 and Equation 2 hold in the case where the number of times of executions reaches the predetermined number of times or the bit error rate is the predetermined rate or more,
wherein
the first voltage is greater than a maximum voltage applied in the program operation, and the second voltage is greater than a maximum voltage applied in the erase operation,
in the voltage application process, the control circuit is configured to apply the first voltage to the ferroelectric layer by applying a first pulse voltage m times (m is an integer of 1 or more), and apply the second voltage to the ferroelectric layer by applying a second pulse voltage n times (n is an integer of 1 or more), and
when a pulse width of the first pulse voltage is set to a (μsec) and a pulse width of the second pulse voltage is set to b (μsec),
$$0.1 μsec ≦ a \times m < 250 μsec \qquad ( Equation 1 )$$
$$0.1 μsec ≦ b \times n < 250 μsec . \qquad ( Equation 2 )$$

15. The method for controlling a memory system according to claim 14, wherein waveforms of the first pulse voltage and the second pulse voltage are substantially rectangular.

16. The method for controlling a memory system according to claim 14, wherein the control circuit alternately applies the first pulse voltage and the second pulse voltage to the ferroelectric layer.

17. The method for controlling a memory system according to claim 14,
wherein
the first voltage is positive,
an absolute value of the first voltage is 3.0 V or more,
the second voltage is negative, and
an absolute value of the second voltage is 2.0 V or more.
